(19) United States
(12) Patent Application Publication
(10) Pub. No.: US 2023/0275054 A1
(43) Pub. Date: Aug. 31, 2023

(54) SEMICONDUCTOR DEVICES AND DATA STORAGE SYSTEMS INCLUDING THE SAME

(71) Applicant: SAMSUNG ELECTRONICS CO., LTD., SUWON-SI, GYEONGGI-DU (KR)

(72) Inventors: YUNSUN JANG, Suwon-si, Gyeonggi-do (KR); Moorym CHOI, Suwon-si, Gyeonggi-do (KR)

(21) Appl. No.: 18/086,086

(22) Filed: Dec. 21, 2022

(30) Foreign Application Priority Data
Feb. 25, 2022 (KR) 10-2022-0025188

(51) Int. Cl. H01L 23/00; H10B 41/27; H10B 43/27; H01L 25/065; H01L 25/18; H01L 25/00

(52) U.S. Cl. CPC H01L 24/08; H01L 27/11556; H01L 27/11582; H01L 25/0657; H01L 25/18; H01L 24/80; H01L 25/50; H01L 2224/08145; H01L 2224/80006; H01L 2224/80895; H01L 2224/80896; H01L 2924/1431; H01L 2924/14511

(57) ABSTRACT

A semiconductor device includes a first substrate structure including a substrate, circuit elements, and first bonding metal layers, and a second substrate structure directly on the first substrate structure. The second substrate structure includes a plate layer comprising a conductive material, gate electrodes stacked below the plate layer, channel structures passing through the gate electrodes and each including a channel layer, separation regions penetrating through the gate electrodes and extending in first and second directions and source contacts in the plate layer and disposed on the separation regions. The source contacts extend in the second direction. Second bonding metal layers are connected to the first bonding metal layers. The plate layer is in direct contact with lateral side surfaces of the source contacts and an upper end of the channel layer of each of the channel structures, and is electrically connected to the source contacts and the channel layer.

### CROSS-REFERENCE TO RELATED APPLICATION(S)

This application claims priority under 35 U.S.C. § 119 to Korean Patent Application No. 10-2022-0025188, filed on Feb. 25, 2022 in the Korean Intellectual Property Office, the disclosure of which is incorporated by reference in its entirety herein.

### 1. TECHNICAL FIELD

Embodiments of the present inventive concept relate to a semiconductor device and a data storage system including the same.

### 2. DISCUSSION OF RELATED ART

There is an increased demand for semiconductor devices capable of storing high-capacity data for data storage systems. Accordingly, methods for increasing the data storage capacity of a semiconductor device are being researched. For example, a semiconductor device including memory cells arranged three-dimensionally instead of two-dimensionally arranged memory cells is being developed to increase the data storage capacity of a semiconductor device.

### SUMMARY

Embodiments of the present inventive concept provide a semiconductor device having increased electrical characteristics and reliability.

Embodiments of the present inventive concept provide a data storage system including a semiconductor device having increased electrical characteristics and reliability.

According to an embodiment of the present inventive concept, a semiconductor device includes a first substrate structure including a substrate, circuit elements on the substrate, and first bonding metal layers on the circuit elements. A second substrate structure is disposed directly on the first substrate structure. The second substrate structure is electrically connected to the first substrate structure. The second substrate structure includes a plate layer comprising a conductive material. Gate electrodes are stacked below the plate layer and are spaced apart from each other in a first direction that is perpendicular to a lower surface of the plate layer. Channel structures pass through the gate electrodes and extend in the first direction. Each of the channel structures includes a channel layer. Separation regions extend in the first direction and a second direction that is perpendicular to the first direction. The separation regions penetrate through the gate electrodes and are spaced apart from each other in a third direction that is perpendicular to the first and second directions. Source contacts are in the plate layer and are disposed on the separation regions. The source contacts extend in the second direction. Second bonding metal layers are below the channel structures and the gate electrodes and are directly connected to the first bonding metal layers. The plate layer is in direct contact with lateral side surfaces of the source contacts and an upper end of the channel layer of each of the channel structures, and is electrically connected to the source contacts and the channel layer.

According to an embodiment of the present inventive concept, a semiconductor device includes a first substrate structure including a substrate and circuit elements on the substrate. A second substrate structure is disposed directly on the first substrate structure. The second substrate structure is electrically connected to the first substrate structure. The second substrate structure includes a plate layer. Gate electrodes are stacked below the plate layer and are spaced apart from each other in a first direction that is perpendicular to a lower surface of the plate layer. Channel structures pass through the gate electrodes and extend in the first direction. Each of the channel structures includes a channel layer. Separation regions extend in the first direction and a second direction that is perpendicular to the first direction. The separation regions penetrate through the gate electrodes and are spaced apart from each other in a third direction that is perpendicular to the first and second directions. Source contacts are in the plate layer and are disposed on the separation regions. The source contacts extend in the second direction. At least one source interconnection layer is on upper surfaces or first side surfaces of the source contacts. The at least one source interconnection layer is electrically connected to the source contacts. The source contacts have second side surfaces in direct contact with the plate layer, and lower surfaces of the source contacts are in direct contact with the separation regions.

According to an embodiment of the present inventive concept, a data storage system includes a semiconductor storage device including a first substrate structure having circuit elements and first bonding metal layers, a second substrate structure including channel structures and second bonding metal layers connected to the first bonding metal layers, and an input/output pad electrically connected to the circuit elements. A controller is electrically connected to the semiconductor storage device through the input/output pad and controls the semiconductor storage device. The second substrate structure further includes a plate layer. Gate electrodes are stacked below the plate layer and are spaced apart from each other in a first direction that is perpendicular to a lower surface of the plate layer. Separation regions extend in the first direction and a second direction that is perpendicular to the first direction. The separation regions penetrate through the gate electrodes and are spaced apart from each other in a third direction that is perpendicular to the first and second directions. Source contacts are in the plate layer and are disposed on the separation regions. The source contacts extend in the second direction. At least one source interconnection layer is on upper surfaces or first side surfaces of the source contacts. The at least one source interconnection layer is electrically connected to the source contacts. The source contacts have second side surfaces in direct contact with the plate layer.

### BRIEF DESCRIPTION OF DRAWINGS

The above and other aspects, features, and advantages of the present inventive concept will be more clearly understood from the following detailed description, taken in conjunction with the accompanying drawings, in which:

FIG. 1 is a schematic plan view of a semiconductor device according to an embodiment of the present inventive concept;

FIG. 2 is a schematic cross-sectional view of a semiconductor device according to an embodiment of the present inventive concept;

FIGS. 3A and 3B are partially enlarged views of a semiconductor device taken from areas A and B of FIG. 2, respectively, according to embodiments of the present inventive concept;

FIG. 4 is a perspective view of a semiconductor device according to an embodiment of the present inventive concept;

FIG. 5A is a cross-sectional view of a semiconductor device according to an embodiment of the present inventive concept;

FIG. 5B is a partially enlarged view of a semiconductor device taken from area A of FIG. 5A according to an embodiment of the present inventive concept;

FIG. 6 is a perspective view of a semiconductor device according to an embodiment of the present inventive concept;

FIG. 7 is a schematic plan view of a semiconductor device according to an embodiment of the present inventive concept;

FIGS. 8A and 8B are schematic cross-sectional views of a semiconductor device according to embodiments of the present inventive concept;

FIG. 9 is a perspective view of a semiconductor device according to an embodiment of the present inventive concept;

FIGS. 10A and 10B are partially enlarged views of semiconductor devices according to embodiments of the present inventive concept;

FIG. 11A is a cross-sectional view of a semiconductor device according to an embodiment of the present inventive concept;

FIG. 11B is a partially enlarged view of a semiconductor device taken from area A of FIG. 11A according to an embodiment of the present inventive concept;

FIG. 12 is a cross-sectional view of a semiconductor device according to an embodiment of the present inventive concept;

FIGS. 13A to 13K are schematic cross-sectional views illustrating a method of manufacturing a semiconductor device according to embodiments of the present inventive concept;

FIG. 14 is a diagram schematically illustrating a data storage system including a semiconductor device according to an embodiment of the present inventive concept;

FIG. 15 is a schematic perspective view of a data storage system including a semiconductor device according to an embodiment of the present inventive concept; and

FIG. 16 is a cross-sectional view taken along line III-III′ of FIG. 15 schematically illustrating a semiconductor package according to an embodiment of the present inventive concept.

### DETAILED DESCRIPTION OF EMBODIMENTS

Hereinafter, embodiments of the present inventive concept will be described with reference to the accompanying drawings. Hereinafter, with the exception of cases indicated by reference numerals, terms such as ‘on’, ‘upper portion’, ‘upper surface’, ‘below’, ‘lower portion’, ‘lower surface’, ‘side surface’ and the like may be understood as being referred based on the drawings.

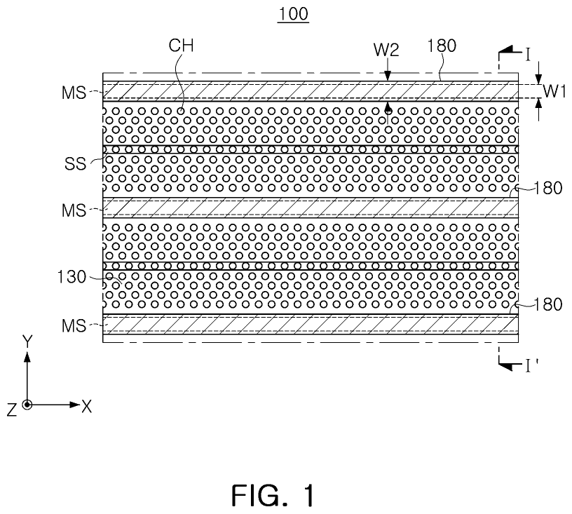

FIG. 1 is a schematic plan view of a semiconductor device according to an embodiment.

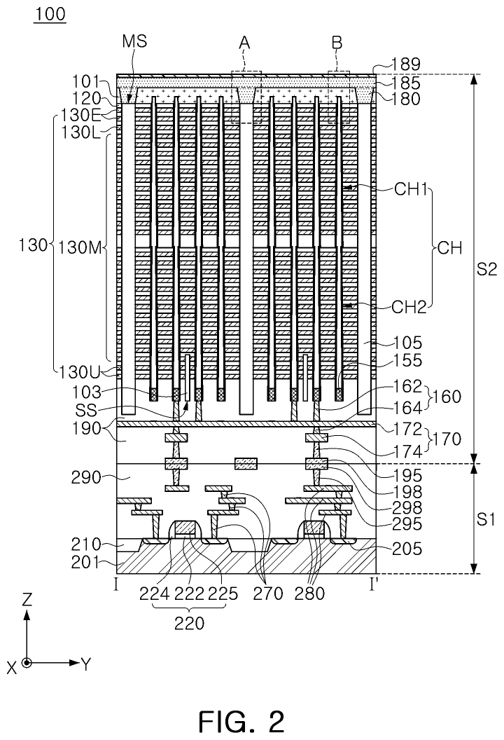

FIG. 2 is a schematic cross-sectional view of a semiconductor device according to an embodiment. FIG. 2 illustrates a cross-section taken along line I-I′ of FIG. 1.

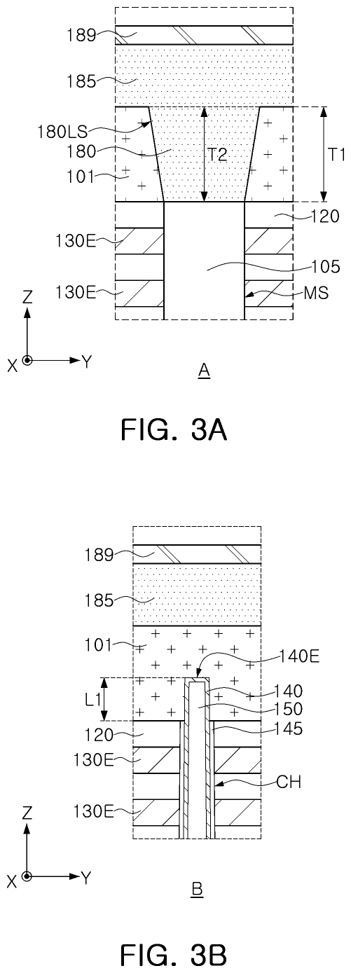

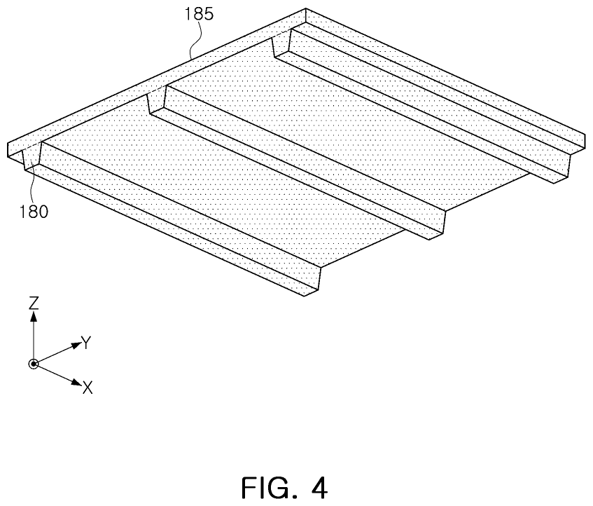

FIGS. 3A and 3B are partially enlarged views of a semiconductor device according to embodiments. FIG. 3A is an enlarged view of area ‘A’ of FIG. 2, and FIG. 3B is an enlarged view of area ‘B’ of FIG. 2.

FIG. 4 is a perspective view of some configurations of a semiconductor device according to an embodiment.

Referring to FIGS. 1 to 4, a semiconductor device 100 includes first and second substrate structures S1 and S2 stacked vertically (e.g., in the Z direction). For example, in an embodiment the first substrate structure S1 may include a peripheral circuit region of the semiconductor device 100, and the second substrate structure S2 may include a memory cell region of the semiconductor device 100. In FIG. 1, the arrangement of the second substrate structure S2 in a plane is illustrated while omitting some components including a plate layer 101 and a source interconnection layer 185 to facilitate understanding. FIG. 4 illustrates source contacts 180 and the source interconnection layer 185.

The first substrate structure S1 may include a substrate 201, source/drain regions 205 and device isolation layers 210 in the substrate 201, and circuit elements 220, circuit contact plugs 270, circuit interconnection lines 280, a peripheral region insulating layer 290, first bonding vias 295, and first bonding metal layers 298 which are disposed on the substrate 201.

In an embodiment, the substrate 201 may have an upper surface extending in the X direction and the Y direction. The device isolation layers 210 may be disposed in the substrate 201 to define an active region. The source/drain regions 205 including impurities may be disposed in a portion of the active region. In an embodiment, the substrate 201 may include a semiconductor material, for example, a group IV semiconductor, a group III-V compound semiconductor, or a group II-VI compound semiconductor. For example, the substrate 201 may be provided as a single crystal bulk wafer.

The circuit elements 220 may include a planar transistor. Each of the circuit elements 220 may include a circuit gate dielectric layer 222, spacer layers 224, and a circuit gate electrode 225. The source/drain regions 205 may be disposed in the substrate 201, on both sides of the circuit gate electrode 225 (e.g., lateral sides in the Y direction).

The peripheral region insulating layer 290 may be disposed on the circuit element 220 and on the substrate 201. The circuit contact plugs 270 and the circuit interconnection lines 280 may constitute a first interconnection structure of the first substrate structure S1. The circuit contact plugs 270 may have a cylindrical shape and may pass through the peripheral region insulating layer 290 to be connected to the source/drain regions 205. An electrical signal may be applied to the circuit element 220 by the circuit contact plugs 270. In an embodiment, the circuit contact plugs 270 may also be connected to the circuit gate electrode 225. The circuit interconnection lines 280 may be connected to the circuit contact plugs 270, have a line shape, and may be disposed in a plurality of layers. While an embodiment of FIG. 2 shows the circuit interconnection lines 280 and the circuit contact plugs 270 disposed in three layers, embodiments of the present inventive concept are not necessarily limited thereto and the number of layers of the circuit contact plugs 270 and the circuit interconnection lines 280 may be variously changed.

The first bonding vias 295 and the first bonding metal layers 298 may constitute a first bonding structure and may be disposed on a portion of uppermost circuit interconnection lines 280. In an embodiment, the first bonding vias 295 may have a cylindrical shape, and the first bonding metal layers 298 may have a circular pad shape or a relatively short line shape on a plane. However, embodiments of the present inventive concept are not necessarily limited thereto. Upper surfaces of the first bonding metal layers 298 may be exposed to the upper surface of the first substrate structure S1. The first bonding vias 295 and the first bonding metal layers 298 may function as bonding structures or bonding layers of the first substrate structure S1 and the second substrate structure S2. In addition, the first bonding vias 295 and the first bonding metal layers 298 may provide an electrical connection path with the second substrate structure S2. In an embodiment, a portion of the first bonding metal layers 298 may be disposed only for bonding without being connected to the lower circuit interconnection lines 280 as illustrated in FIG. 2. The first bonding vias 295 and the first bonding metal layers 298 may include a conductive material, such as copper (Cu). However, embodiments of the present inventive concept are not necessarily limited thereto and the conductive material of the first bonding vias 295 and the first bonding metal layers 298 may vary.

In an embodiment, the peripheral region insulating layer 290 may include a bonding insulating layer having a predetermined thickness from the upper surface. The bonding insulating layer may be a layer for dielectric-dielectric bonding with the bonding insulating layer of the second substrate structure S2. The bonding insulating layer may also function as a diffusion barrier layer of the first bonding metal layers 298, and may include, for example, at least one compound selected from SiO, SiN, SiCN, SiOC, SiON, and SiOCN.

The second substrate structure S2 may include a plate layer 101, gate electrodes 130 stacked (e.g., in the Z direction) on the lower surface of the plate layer 101, interlayer insulating layers 120 alternately stacked (e.g., in the Z direction) with the gate electrodes 130, channel structures CH disposed to penetrate through the gate electrodes 130, separation regions MS extending in one direction by penetrating through the gate electrodes 130, and source contacts 180 disposed on (e.g., disposed directly on) the separation regions MS. The second substrate structure S2 may further include upper insulating regions SS passing through a portion of the gate electrodes 130, a cell region insulating layer 190 covering the gate electrodes 130, a source interconnection layer 185 disposed on the source contacts 180 (e.g., disposed directly thereon), and an anti-reflection layer 189 on the source interconnection layer 185 (e.g., disposed directly thereon). The second substrate structure S2 may further include, as a second interconnection structure, cell contact plugs 160 and cell interconnection lines 170 disposed below the gate electrodes 130 and the channel structures CH. The second substrate structure S2 may further include second bonding vias 195 and second bonding metal layers 198, as a second bonding structure.

In an embodiment, the plate layer 101 may have an upper surface extending in the X direction and the Y direction. In an embodiment, the plate layer 101 may function as a common source line of the semiconductor device 100. The plate layer 101 may receive an electrical signal transmitted from the source interconnection layer 185, e.g., an erase voltage, through the source contacts 180, and may transmit the electrical signal to the channel layers 140 of the channel structures CH. The plate layer 101 may directly contact the source contacts 180 and the source interconnection layer 185 and may be electrically connected to the source contacts 180 and the source interconnection layer 185. As illustrated in the enlarged view of FIG. 3B, the plate layer 101 may be in direct contact with an upper end 140E of the channel layer 140 on an upper end of each of the channel structures CH and may be electrically connected to the channel layer 140.

The plate layer 101 may include a conductive material. For example, in an embodiment the plate layer 101 may include a semiconductor material, for example, a group IV semiconductor, a group III-V compound semiconductor, or a group II-VI compound semiconductor. For example, the group IV semiconductor may include silicon, germanium, or silicon-germanium. The plate layer 101 may be provided as a polycrystalline semiconductor layer such as a polycrystalline silicon layer or an epitaxial layer. The plate layer 101 may further include impurities. For example, in an embodiment the entire plate layer 101 may be formed of an n+ polycrystalline silicon layer including first conductivity type, for example, N-type impurities. However, in some embodiments, the plate layer 101 may include a plurality of regions having different concentrations of impurities.

The gate electrodes 130 may be vertically spaced apart and stacked on a lower surface of the plate layer 101 to form a stack structure together with the interlayer insulating layers 120. The stack structure may include vertically stacked lower and upper stack structures. However, embodiments of the present inventive concept are not necessarily limited thereto. For example, in some embodiments the stack structure may be formed of a single stack structure.

In an embodiment, the gate electrodes 130 may include erase gate electrodes 130E constituting an erase transistor used in an erase operation, at least one lower gate electrode 130L constituting a gate of the ground select transistor, memory gate electrodes 130M constituting a plurality of memory cells, and upper gate electrodes 130U constituting gates of the string select transistors. In this embodiment, the lower gate electrode 130L and the upper gate electrodes 130U may be referred to as “lower” and “upper” based on the direction during a manufacturing process. The number of memory gate electrodes 130M constituting memory cells may be determined according to the capacity of the semiconductor device 100. According to an embodiment, the numbers of the upper and lower gate electrodes 130U and 130L and the erase gate electrodes 130E may be 1 to 4 or more, respectively, and have the same as or different structure from the memory gate electrodes 130M. The erase gate electrodes 130E may be disposed on the lower gate electrode 130L and may be used for an erase operation using a gate induced drain leakage (GIDL) phenomenon. In an embodiment, the erase gate electrodes 130E may be further disposed below the upper gate electrodes 130U. In an embodiment, some of the gate electrodes 130, for example, the memory gate electrodes 130M adjacent to the upper or lower gate electrodes 130U and 130L may be dummy gate electrodes.

In an embodiment, the gate electrodes 130 may be disposed to be at least partially separated in a predetermined unit by the separation regions MS in the Y direction. The gate electrodes 130 may form one memory block, between the pair of adjacent separation regions MS. However, embodiments of present inventive concept are not necessarily limited thereto and the configurations of the memory block may vary.

The interlayer insulating layers 120 may be disposed between the gate electrodes 130 (e.g., in the Z direction). Similar to the gate electrodes 130, the interlayer insulating layers 120 may be spaced apart from each other in a direction perpendicular to the lower surface of the plate layer 101 and may be disposed to extend in the X and Y directions. In an embodiment, the interlayer insulating layers 120 may include an insulating material such as silicon oxide or silicon nitride. However, embodiments of the present inventive concept are not necessarily limited thereto and the composition of the insulating material of the interlayer insulating layers 120 may vary.

The channel structures CH may be disposed to be spaced apart from each other while forming rows and columns on the lower surface of the plate layer 101. In an embodiment, the channel structures CH may be disposed to form a grid pattern or may be disposed in a zigzag shape in one direction. The channel structures CH may have a columnar shape, and may have inclined side surfaces such that a width of the channel structures CH decreases as they approach the plate layer 101 according to an aspect ratio. Each of the channel structures CH may have a connection form in which first and second channel structures CH1 and CH2 penetrating through the upper and lower stack structures of the gate electrodes 130 are connected, respectively, and may have a bent portion due to the difference or change of a width in the connection region.

The channel layer 140 may be disposed in the channel structure CH. In an embodiment, the channel layer 140 may be formed in an annular shape surrounding a channel filling insulating layer 150 therein. However, embodiments of the present inventive concept are not necessarily limited thereto. For example, in an embodiment the channel layer 140 may have a pillar shape such as a cylinder or a prism, without the channel filling insulating layer 150. The channel layer 140 may include a semiconductor material such as polycrystalline silicon or single crystal silicon. The channel layer 140 may further include impurities by doping, for example, N-type impurities in a region parallel to the erase gate electrodes 130E.

As illustrated in FIG. 3B, on the upper end of the channel structure CH, the upper end 140E of the channel layer 140 may be exposed by a channel dielectric layer 145. The upper end 140E of the channel layer 140 may include an upper surface and an upper region of a lateral side surface connected to the upper surface. The upper end 140E of the channel layer 140 may be in direct contact with the plate layer 101 and may be surrounded by the plate layer 101. In this embodiment, the channel layer 140 may be physically and electrically connected to the plate layer 101. In an embodiment, a length L1 or a height of the upper end 140E of the channel layer 140 (e.g., in the Z direction) may be variously changed. In some embodiments, the channel dielectric layer 145 may have a form in which a portion is removed even below the plate layer 101, and in the region in which the channel dielectric layer 145 is removed, the plate layer 101 may partially extend downwardly along the channel layer 140.

The channel dielectric layer 145 may be disposed between the gate electrodes 130 and the channel layer 140. The channel dielectric layer 145 may extend vertically along the channel layer 140. In some embodiments, the channel dielectric layer 145 may further include a layer extending horizontally along upper and lower surfaces of the gate electrodes 130 and covering side surfaces of the gate electrodes 130 facing the channel structure CH. In an embodiment, the channel dielectric layer 145 may include a tunneling layer, a charge storage layer, and a blocking layer sequentially stacked from the channel layer 140. The tunneling layer may tunnel charges into the charge storage layer, and may include, for example, silicon oxide (SiO₂), silicon nitride (S1₃N₄), silicon oxynitride (SiON), or combinations thereof. The charge storage layer may be a charge trap layer or a floating gate conductive layer. The blocking layer may include silicon oxide (SiO₂), silicon nitride (Si₃N₄), silicon oxynitride (SiON), a high-k dielectric material, or combinations thereof.

The channel pad 155 may be disposed only on the lower end of the lower second channel structure CH2. The channel pads 155 may include, for example, a doped semiconductor layer. For example, in an embodiment the channel pads 155 may be formed of polycrystalline silicon containing the same first conductivity type as the plate layer 101, for example, N-type impurities.

The channel layer 140, the channel dielectric layer 145, and the channel filling insulating layer 150 may be connected to each other between the first channel structure CH1 and the second channel structure CH2. A relatively thick interlayer insulating layer 120 may be further disposed between the first channel structure CH1 and the second channel structure CH2. However, the shape of the interlayer insulating layers 120 may be variously changed in embodiments of the present inventive concept.

The separation regions MS may be disposed to extend in the X direction by penetrating through the gate electrodes 130. The separation regions MS may be disposed parallel to each other. The separation regions MS may penetrate through all of the gate electrodes 130 stacked on the plate layer 101 to be connected to the lower surface of the plate layer 101.

As illustrated in FIG. 2, an isolation insulating layer 105 may be disposed in the separation regions MS. In an embodiment, the isolation insulating layer 105 may have a shape in which the width decreases toward the plate layer 101 due to a high aspect ratio. However, the shape of the isolation insulating layer 105 is not necessarily limited thereto. In an embodiment, the isolation insulating layer 105 may include an insulating material, for example, silicon oxide, silicon nitride, or silicon oxynitride.

The source contacts 180 are disposed in the plate layer 101 and on (e.g., directly on) the separation regions MS and may extend in one direction, such as the X direction. In an embodiment, the source contacts 180 may have a line shape, and may be disposed in a region from which the plate layer 101 has been partially removed. The source contacts 180 together with the source interconnection layer 185 may form a source interconnection structure for applying an electrical signal to the plate layer 101. The source contacts 180 may be in direct contact with the plate layer 101 through lateral side surfaces 180LS to be electrically connected to the plate layer 101. Accordingly, the source contacts 180 may transmit an electrical signal from the source interconnection layer 185 to the plate layer 101.

The source contacts 180 may pass through the plate layer 101 (e.g., pass completely therethrough) and lower surfaces of the source contacts 180 may directly contact the isolation insulating layers 105. In some embodiments, the lower surfaces of the source contacts 180 may directly contact the isolation insulating layer 105 and the interlayer insulating layer 120. The lower surfaces of the source contacts 180 may be coplanar with the lower surface of the plate layer 101 (e.g., in the Z direction). Upper surfaces of the source contacts 180 may be coplanar with the upper surface of the plate layer 101 (e.g., in the Z direction). The lateral side surfaces 180LS of the source contacts 180 may have inclined side surfaces such that a width becomes narrower as they get closer to the separation regions MS and the width increases as they get closer to the source interconnection layer 185. However, embodiments of the present inventive concept are not necessarily limited thereto and the shape of the lateral side surfaces 180LS may vary.

As illustrated in an embodiment shown in FIG. 1, a second width W2 of the source contacts 180 in the Y direction may be greater than a first width W1 of the separation regions MS. However, embodiments of the present inventive concept are not necessarily limited thereto. The first and second widths W1 and W2 may refer to a maximum width or a width on an upper end. In some embodiments, the second width W2 of the source contacts 180 in the Y direction may be less than or equal to the first width W1 of the separation regions MS.

As illustrated in an embodiment of FIG. 3A, a second thickness T2 (e.g., length in the Z direction) of the source contact 180 may be substantially the same as a first thickness T1 of the plate layer 101. Accordingly, the source contact 180 may be disposed to completely penetrate through the plate layer 101 in a thickness direction, for example, the Z direction. In an embodiment, the first thickness T1 of the plate layer 101 may be in a range of about 10 nm to about 150 nm. However, embodiments of the present inventive concept are not necessarily limited thereto.

The source interconnection layer 185 may be disposed on (e.g., disposed directly thereon) the source contacts 180 to be connected to the source contacts 180. As illustrated in FIG. 4, the source interconnection layer 185 may have a plate shape extending in the X direction and the Y direction. The source interconnection layer 185 may cover an upper surface of the plate layer 101 and may directly contact the plate layer 101. The source interconnection layer 185 may transmit an electrical signal to the plate layer 101 through the source contacts 180.

In an embodiment, the source interconnection layer 185 may be connected to, for example, an input/output pad of the semiconductor device 100 to receive an electrical signal directly from the outside (e.g., an external source). The source interconnection layer 185 may also receive an electrical signal from the circuit elements 220 of the first substrate structure S1 through contact plugs disposed on outer regions of the gate electrodes 130. Accordingly, in contrast to a comparative embodiment in which an electrical signal is applied through the plate layer 101 without the source contacts 180 and the source interconnection layer 185, resistance may be reduced and noise may be reduced in embodiments of the present inventive concept. Since the electrical signal is applied through the source contacts 180 disposed on the separation regions MS, the signal may be uniformly applied regardless of positions of the channel structures CH.

The anti-reflection layer 189 may be disposed on (e.g., disposed directly on) the upper surface of the source interconnection layer 185, and may function to prevent light reflection by the source interconnection layer 185. However, embodiments of the present inventive concept are not necessarily limited thereto. For example, in some embodiments, the anti-reflection layer 189 may be omitted, such as depending on the material of the source interconnection layer 185.

The source contacts 180, the source interconnection layer 185, and the anti-reflection layer 189 may include a metal material, for example, aluminum (Al), copper (Cu), tungsten (W), titanium (Ti), tungsten nitride (WN), tantalum nitride (TaN), titanium nitride (TiN), or combinations thereof. However, embodiments of the present inventive concept are not necessarily limited thereto. In an embodiment, the source contacts 180 and the source interconnection layer 185 may be formed together in the same deposition process and may be formed of the same material. Accordingly, in the drawings, the interface between the source interconnection layer 185 and the source contacts 180 is illustrated with a dotted line as the source interconnection layer 185 and the source contacts 180 may be integral with each other in some embodiments. For example, the source contacts 180 and the source interconnection layer 185 may include aluminum (Al), and the anti-reflection layer 189 may include titanium (Ti). In some embodiments, the source contacts 180 and the source interconnection layer 185 may be formed by different deposition processes and may include different materials.

Since the source contacts 180 include a metal material while the separation regions MS include an insulating material, the directions of stress are different from each other. Therefore, the total stress in the semiconductor device 100 may be reduced and reliability may be increased.

As illustrated in FIG. 1, the upper insulating regions SS may extend between the separation regions MS in the X direction. The upper insulating regions SS may be disposed to penetrate through a portion of the gate electrodes 130 including a lowermost upper gate electrode 130U among the gate electrodes 130. As illustrated in an embodiment of FIG. 2, the upper insulating regions SS may separate a total of three gate electrodes 130 including the upper gate electrodes 130U in the Y direction from each other. However, embodiments of the present inventive concept are not necessarily limited thereto and the number of gate electrodes 130 separated by the upper insulating regions SS may vary. The upper gate electrodes 130U separated by the upper insulating regions SS may form different string select lines. An upper insulating layer 103 may be disposed in the upper insulating regions SS. In an embodiment, the upper insulating layer 103 may include an insulating material, for example, silicon oxide, silicon nitride, or silicon oxynitride.

The cell region insulating layer 190 may be disposed to cover the plate layer 101 and the gate electrodes 130 on the lower surface of the plate layer 101. The cell region insulating layer 190 may be formed of an insulating material, and may be formed of a plurality of insulating layers.

The second interconnection structure may include cell contact plugs 160 and cell interconnection lines 170, and may be configured such that the second substrate structure S2 is electrically connected to the first substrate structure S1.

In an embodiment, the cell contact plugs 160 may include first and second cell contact plugs 162 and 164, and the cell interconnection lines 170 may include first and second cell interconnection lines 172 and 174. Lower ends of the channel pads 155 may be directly connected to the first cell contact plugs 162. Lower ends of the first cell contact plugs 162 may be directly connected to the first cell interconnection lines 172. The second cell contact plugs 164 may vertically connect the first and second cell interconnection lines 172 and 174 to each other.

In an embodiment, the cell contact plugs 160 may have a cylindrical shape. The cell contact plugs 160 may have different lengths. For example, the first cell contact plugs 162 may have a relatively large length. In an embodiment, the cell contact plugs 160 may have inclined side surfaces that have a width that decreases as they get closer to the plate layer 101 and increases as they get closer to the first substrate structure S1 depending on the aspect ratio.

The cell interconnection lines 170 may have a line shape extending in at least one direction. The first cell interconnection lines 172 may include bit lines connected to the channel structures CH. The second cell interconnection lines 174 may be interconnection lines disposed below the first cell interconnection lines 172. The cell interconnection lines 170 may have side surfaces that are inclined so that the width decreases as they get closer to the plate layer 101.

In an embodiment, the cell contact plugs 160 and the cell interconnection lines 170 may include, for example, tungsten (W), aluminum (Al), copper (Cu), tungsten nitride (WN), tantalum nitride (TaN), titanium nitride (TiN), or combinations thereof.

The second bonding vias 195 of the second bonding structure may be disposed below the second cell interconnection lines 174 to be connected to (e.g., directly connected to) the second cell interconnection lines 174, and the second bonding metal layers 198 of the second bonding structure may be connected to (e.g., directly connected to) the second bonding vias 195. Lower surfaces of the second bonding metal layers 198 may be exposed to a lower surface of the second substrate structure S2. The second bonding metal layers 198 may be bonded to and connected to the first bonding metal layers 298 of the first substrate structure S1. The second bonding vias 195 and the second bonding metal layers 198 may include a conductive material, for example, copper (Cu).

In an embodiment, the cell region insulating layer 190 may include a bonding insulating layer having a predetermined thickness from the lower surface. In this embodiment, the bonding insulating layer may form a dielectric-dielectric bonding with the bonding insulating layer of the first substrate structure S1. In an embodiment, the bonding insulating layer may include at least one compound selected from SiO, SiN, SiCN, SiOC, SiON, and SiOCN.

In an embodiment, the first and second substrate structures S1 and S2 may be bonded by bonding the first bonding metal layers 298 and the second bonding metal layers 198 to each other and by bonding the bonding insulating layers to each other. In an embodiment, the bonding of the first bonding metal layers 298 and the second bonding metal layers 198 may be, for example, a copper (Cu)-to-copper (Cu) bonding, and the bonding of the bonding insulating layers may be, for example, a dielectric-to-dielectric bonding such as SiCN-to-SiCN bonding. The first and second substrate structures S1 and S2 may be bonded by hybrid bonding including copper (Cu)-to-copper (Cu) bonding and dielectric-to-dielectric bonding.

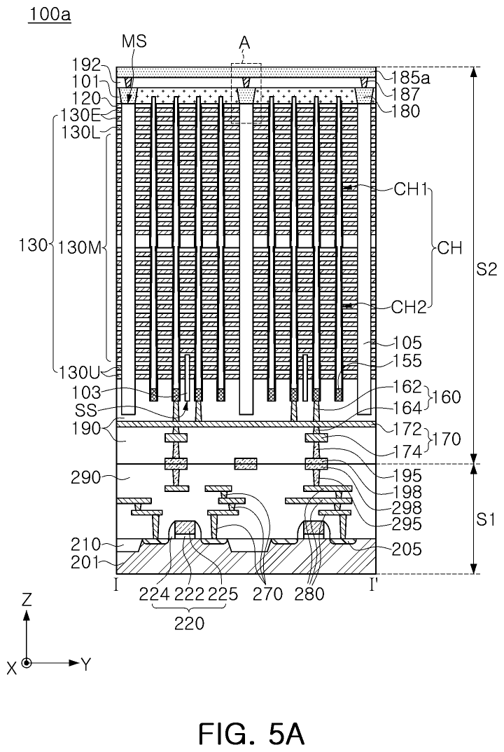

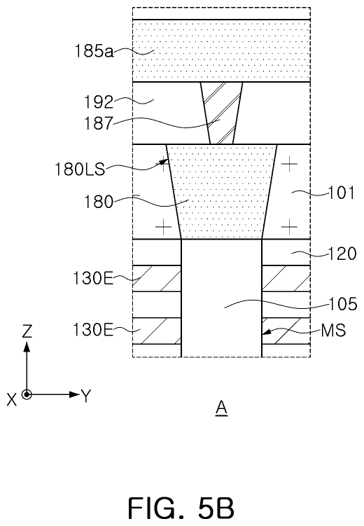

FIGS. 5A and 5B are cross-sectional views and partially enlarged views illustrating a semiconductor device according to embodiments of the present inventive concept. FIGS. 5A and 5B illustrate regions corresponding to FIGS. 2 and 3A, respectively.

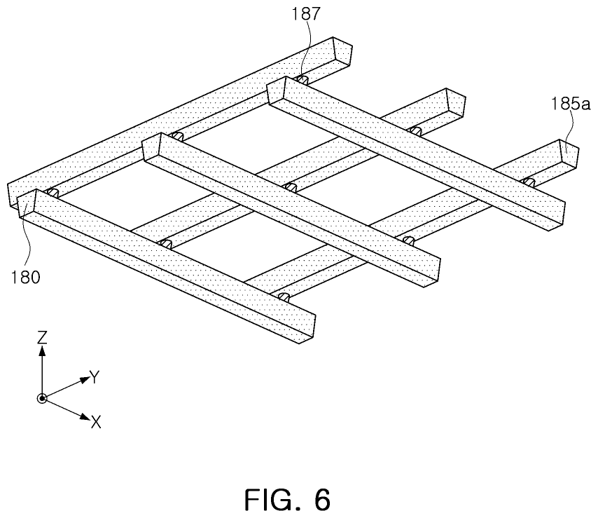

FIG. 6 is a perspective view of a configuration of a semiconductor device according to an embodiment of the present inventive concept.

Referring to FIGS. 5A to 6, a semiconductor device 100a may further include vias 187 disposed between source contacts 180 and source interconnection layers 185a (e.g., in the Z direction). Also, in the semiconductor device 100a, the source interconnection layers 185a may have a line shape and may be arranged in a plurality of layers.

As illustrated in FIG. 6, each of the source interconnection layers 185a may have a line shape extending in a direction intersecting the source contacts 180, for example, a Y direction. However, embodiments of the present inventive concept are not necessarily limited thereto. The vias 187 may be disposed between the source contacts 180 and the source interconnection layers 185a in the Z direction in regions in which the source contacts 180 and the source interconnection layers 185a intersect each other.

In an embodiment, each of the vias 187 may have a cylindrical shape. A diameter or width of each of the vias 187 in the X direction may be less than a width of each of the source contacts 180 in the X direction. The semiconductor device 100a may further include an upper cell region insulating layer 192 on the source contacts 180, and the vias 187 may pass through the upper cell region insulating layer 192 to be connected to (e.g., directly connected to) the source contacts 180. In an embodiment, the vias 187 may include a metal material, for example, tungsten (W), aluminum (Al), copper (Cu), tungsten nitride (WN), tantalum nitride (TaN), titanium nitride (TiN), or combinations thereof.

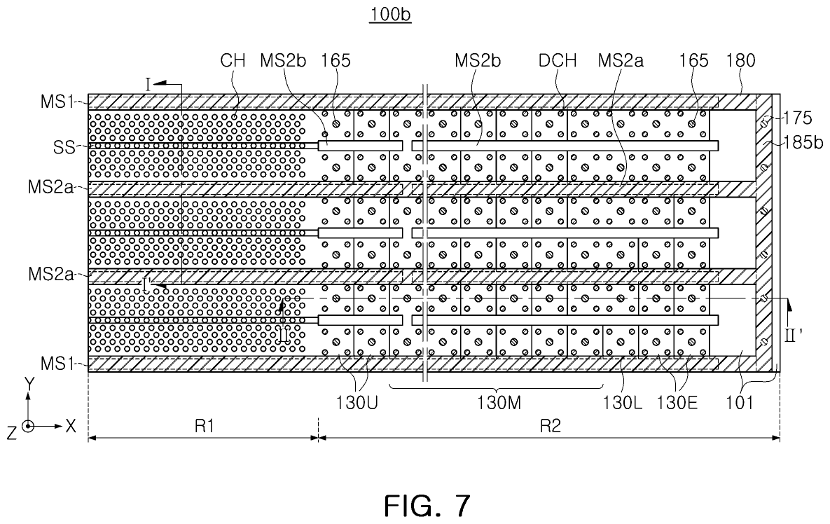

FIG. 7 is a schematic plan view of a semiconductor device according to an embodiment of the present inventive concept.

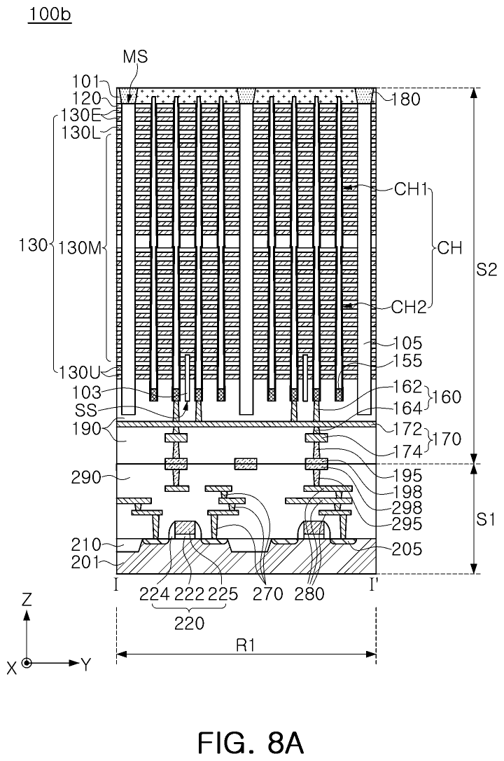

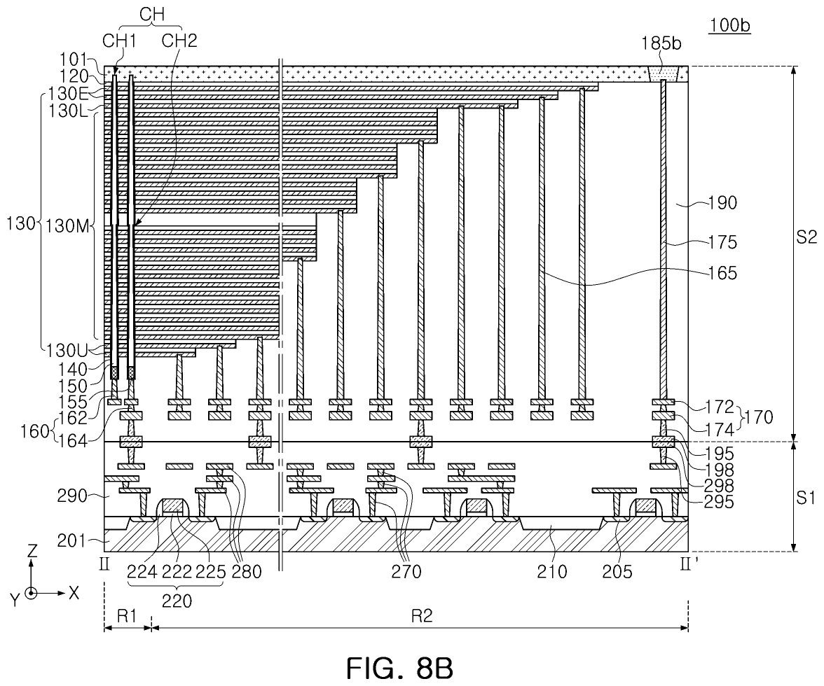

FIGS. 8A and 8B are schematic cross-sectional views of a semiconductor device according to embodiments of the present inventive concept. FIG. 8A illustrates a cross section taken along line I-I′ of FIG. 7, and FIG. 8B illustrates a cross section taken along line II-II′ of FIG. 7.

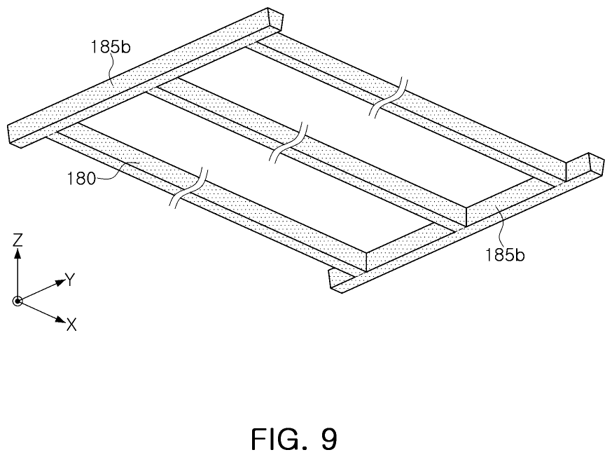

FIG. 9 is a perspective view of some configurations of a semiconductor device according to an embodiment of the present inventive concept.

Referring to FIGS. 7 to 9, a semiconductor device 100b may include a first region R1 and a second region R2, and a source interconnection layer 185b may be disposed in the second region R2. The second substrate structure S2 of the semiconductor device 100b may further include first and second separation regions MS1, MS2a and MS2b, dummy channel structures DCH, gate contacts 165, and source contact plugs 175.

In the semiconductor device 100b, the first region R1 may correspond to the region illustrated in embodiments of FIGS. 1 to 3B. The second region R2 is a region in which the gate electrodes 130 extend to have different lengths and may correspond to a region for electrically connecting the memory cells to the first substrate structure S1. The second region R2 may be disposed on at least one end of the first region R1 in at least one direction, for example, the X direction.

The first and second separation regions MS1, MS2a, and MS2b may correspond to the separation regions MS of embodiments of FIGS. 1 to 3B. In an embodiment shown in FIG. 7 the first separation regions MS1 extend in one layer in the X direction, and the second separation regions MS2a and MS2b may extend intermittently or be disposed only in some areas, between the adjacent pair of first separation regions MS1. For example, in an embodiment the second separation regions MS2a and MS2b may include second central separation regions MS2a, and second auxiliary separation regions MS2b disposed between the first separation region MS1 and the second central separation regions MS2a (e.g., in the Y direction). In an embodiment, the second central separation regions MS2a may be disposed over the first region R1 and the second region R2, and the second auxiliary separation regions MS2b may be disposed only in the second region R2. The second central separation regions MS2a may be disposed to be spaced apart from each other in the second region R2 in the X direction. In some embodiments, a shape in which the second separation regions MS2a and MS2b are spaced apart from each other in the second region R2 may be variously changed. However, embodiments of the present inventive concept are not necessarily limited thereto and the arrangement order and number of the first and second separation regions MS1, MS2a, and MS2b may vary.

The gate electrodes 130 may be disposed to form a step difference in the X direction as illustrated in FIG. 8B and also to form a step difference in the Y direction. Due to the step difference, predetermined regions in the gate electrodes 130, including the ends of the gate electrodes 130, may be exposed. The gate electrodes 130 may be connected to the gate contacts 165 in the above regions.

The gate contacts 165 may be disposed in the second region R2 and may pass through the cell region insulating layer 190 and upper ends of the gate contacts 165 may be connected to (e.g., directly connected to) the gate electrodes 130. Lower ends of the gate contacts 165 may be connected to (e.g., directly connected to) the first cell interconnection lines 172. The gate contacts 165 may include a conductive material.

The dummy channel structures DCH may be disposed around the gate contacts 165 in the second region R2. In an embodiment, the dummy channel structures DCH may have the same internal structure as the channel structures CH or may have a structure filled with only an insulating material.

The source interconnection layer 185b may be disposed on at least one end of the source contacts 180 in the X direction. As illustrated in FIG. 9, in an embodiment in which the second regions R2 are positioned on both sides of the first region R1 in the X direction, the source interconnection layer 185b may be disposed on both ends of the source contacts 180 in the X direction. The source interconnection layer 185b may be disposed outside the gate electrodes 130 in the second region R2. However, embodiments of the present inventive concept are not necessarily limited thereto and the position of the source interconnection layer 185b in the second region R2 may be variously changed. For example, in some embodiments, the source interconnection layer 185b may be positioned on the gate electrodes 130 to overlap the gate electrodes 130 in the second region R2.

The source interconnection layer 185b may be disposed to be connected to side surfaces (e.g., end portions) of the source contacts 180. In an embodiment, the source interconnection layer 185b may be disposed on substantially the same level as the source contacts 180 and may be disposed at substantially the same thickness. For example, upper and lower surfaces of the source interconnection layer 185b may be coplanar with upper and lower surfaces of the source contacts 180. The source interconnection layer 185b may be disposed in the plate layer 101, and may be disposed in a region from which the plate layer 101 has been partially removed. The upper and lower surfaces of the source interconnection layer 185b may be coplanar with the upper and lower surfaces of the plate layer 101, respectively. In an embodiment, the source interconnection layer 185b may be formed together in the same process step as the source contacts 180.

The source contact plugs 175 may be disposed below the source interconnection layer 185b and may be connected to (e.g., directly connected to) the source interconnection layer 185b. The source interconnection layer 185b may be electrically connected to the circuit elements 220 of the first substrate structure S1 through the source contact plugs 175. As shown in an embodiment of FIG. 8B, an upper end of the source contact plug 175 may be connected to (e.g., directly connected to) the source interconnection layer 185b, and a lower end thereof may be connected to (e.g., directly connected to) the first cell interconnection line 172. However, embodiments of the present inventive concept are not necessarily limited thereto. For example, in some embodiments, the source contact plugs 175 may be omitted, and in this embodiment, the source interconnection layer 185b may be directly connected to the input/output pad.

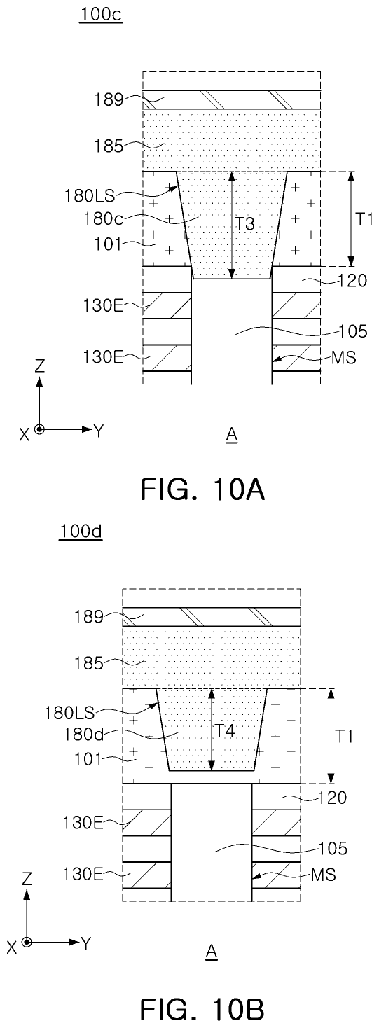

FIGS. 10A and 10B are partially enlarged views of semiconductor devices according to embodiments of the present inventive concept. FIGS. 10A and 10B illustrate regions corresponding to FIG. 3A.

Referring to FIG. 10A, in a semiconductor device 100c, a source contact 180c may be disposed by penetrating through the plate layer 101 and partially recessing the isolation insulating layer 105 of the separation region MS.

The lower surface of the source contact 180c may be positioned on a level lower than the lower surface of the plate layer 101, and may be positioned on a higher level than the upper surface of an uppermost erase gate electrode 130E. The lower surface of the source contact 180c may be positioned on a level co-planar with the interlayer insulating layer 120 on the lower surface of the plate layer 101. A lower surface of the source contact 180c may directly contact the isolation insulating layer 105. In some embodiments, the lower surface of the source contact 180c may be in direct contact with the isolation insulating layer 105 and the interlayer insulating layer 120 depending on the width of the source contact 180c. For example, in an embodiment in which the width of the lower surface of the source contact 180c is greater than the width of the isolation insulating layer 105, the lower surface of the source contact 180c may directly contact both the isolation insulating layer 105 and the interlayer insulating layer 120.

In an embodiment, a third thickness T3 (e.g., length in the Z direction) of the source contact 180c may be greater than a first thickness T1 of the plate layer 101. In this embodiment, the source contact 180c may also be electrically connected to the plate layer 101 through a portion of the lateral side surface 180LS in direct contact with the plate layer 101.

Referring to FIG. 10B, in a semiconductor device 100d according to an embodiment, a source contact 180d may be disposed to only partially penetrate through the plate layer 101.

The lower surface of the source contact 180d may be positioned on a higher level than the lower surface of the plate layer 101. The lower surface of the source contact 180d may be disposed within the plate layer 101 and may be in direct contact with the plate layer 101. In an embodiment, a fourth thickness T4 (e.g., length in the Z direction) of the source contact 180d may be less than the first thickness T1 of the plate layer 101. In an embodiment shown in FIG. 10B, the source contact 180d may be electrically connected to the plate layer 101 through the lateral side surface 180LS and lower surface which directly contacting the plate layer 101.

The embodiments of FIGS. 10A and 10B as described above may also be applied to embodiments shown in FIGS. 5A to 9.

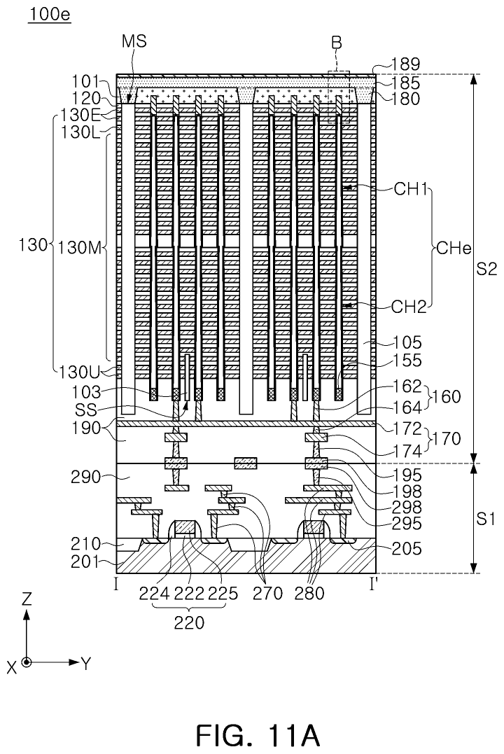

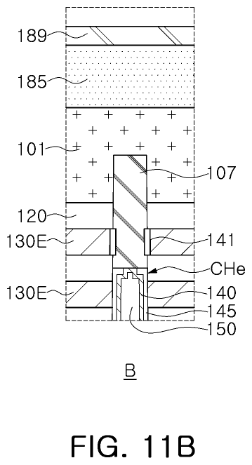

FIGS. 11A and 11B are cross-sectional views and partially enlarged views of a semiconductor device according to embodiments of the present inventive concept. FIGS. 11A and 11B illustrate regions corresponding to FIGS. 2 and 3B, respectively.

Referring to FIGS. 11A and 11B, in a semiconductor device 100e, a channel structure CHe may further include an epitaxial layer 107.

In an embodiment, the epitaxial layer 107 is disposed on the lower surface of the plate layer 101, on the upper end of the channel structure CHe, and may extend below at least one gate electrode 130. The epitaxial layer 107 may be disposed in a recessed region of the plate layer 101. The lower surface of the epitaxial layer 107 may be positioned between the vertically adjacent gate electrodes 130 (e.g., in the Z direction). For example, the lower surface of the epitaxial layer 107 may be positioned between the adjacent erase gate electrodes 130E. However, embodiments of the present inventive concept are not necessarily limited thereto. The epitaxial layer 107 may be connected to (e.g., directly connected to) the channel layer 140 through the lower surface. A gate insulating layer 141 may be further disposed between the epitaxial layer 107 and the erase gate electrode 130E facing the epitaxial layer 107.

In an embodiment, an electrical signal applied from the source interconnection layer 185 may be transmitted to the channel layer 140 through the source contacts 180, the plate layer 101, and the epitaxial layer 107.

The embodiments of FIGS. 11A and 11B may also be applied to embodiments shown in FIGS. 5A to 9 and FIG. 12, and may be combined with embodiments shown in FIGS. 10A and 10B.

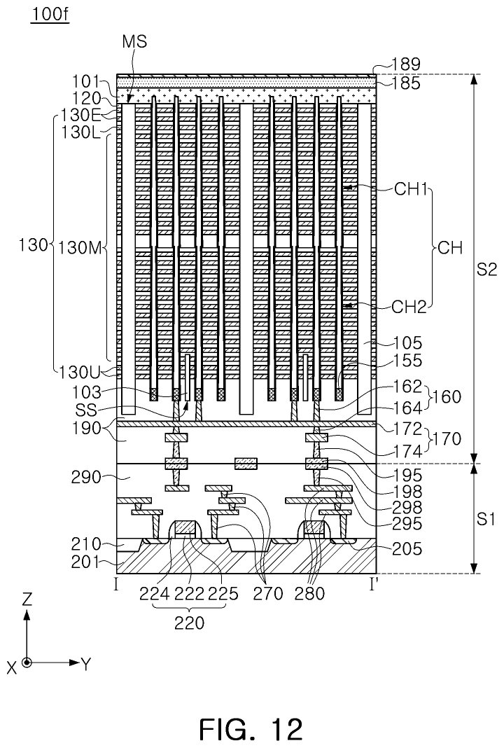

FIG. 12 is a cross-sectional view of a semiconductor device according to an embodiment of the present inventive concept. FIG. 12 illustrates a region corresponding to a region shown in FIG. 2.

Referring to FIG. 12, a semiconductor device 100f may not include the source contacts 180, unlike embodiments shown in FIGS. 1 to 4. In an embodiment shown in FIG. 12, the plate layer 101 may directly contact the source interconnection layer 185 through the upper surface thereof to receive an electrical signal from the source interconnection layer 185.

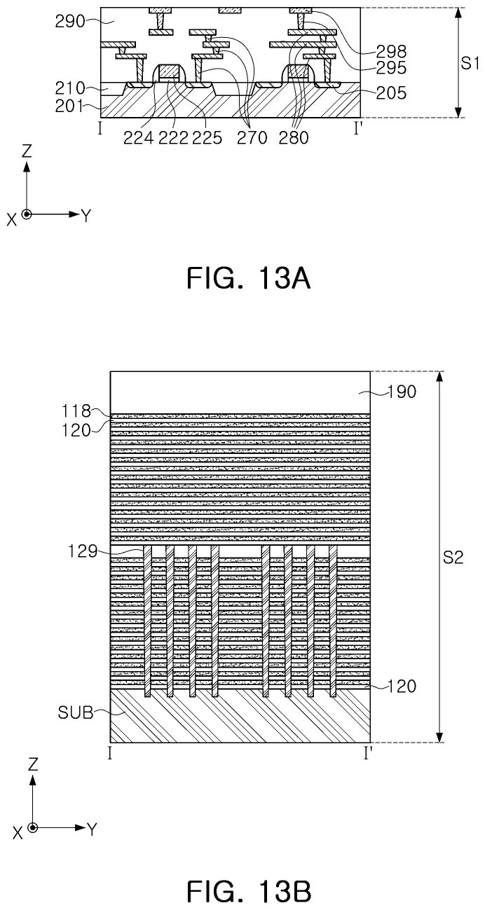

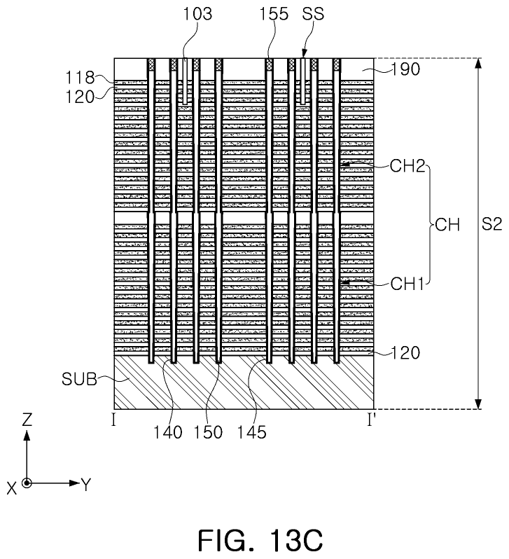

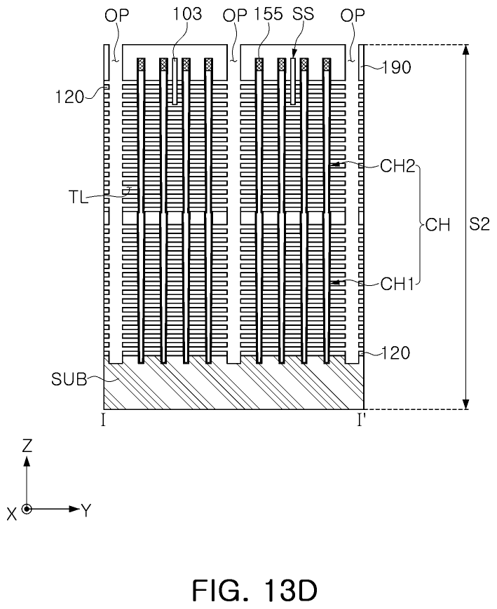

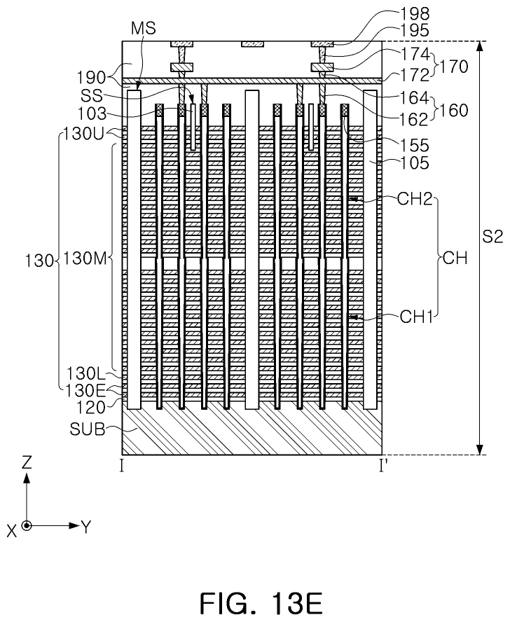

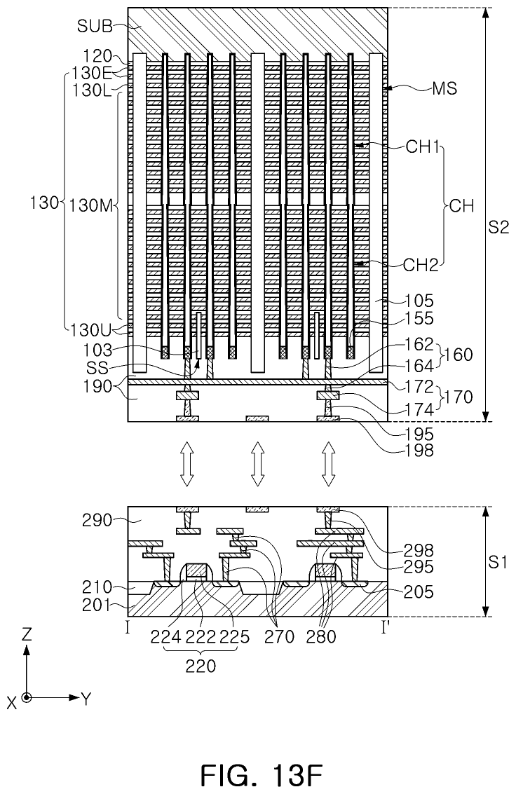

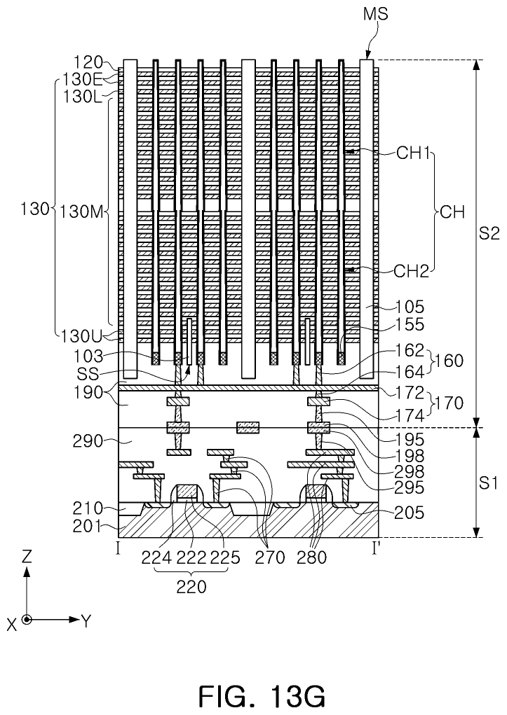

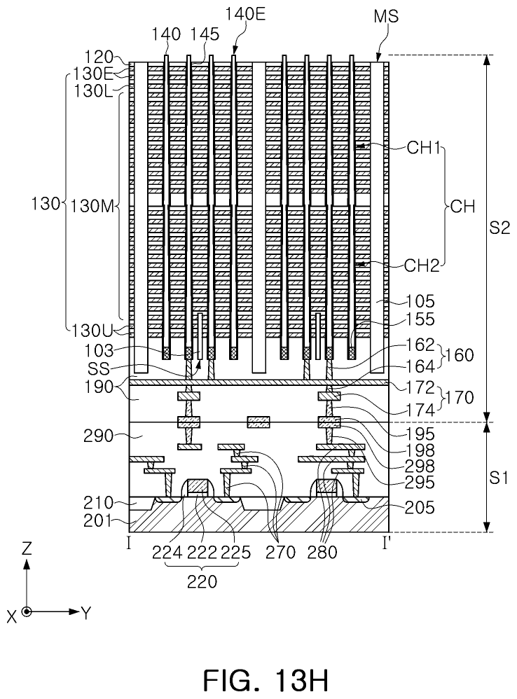

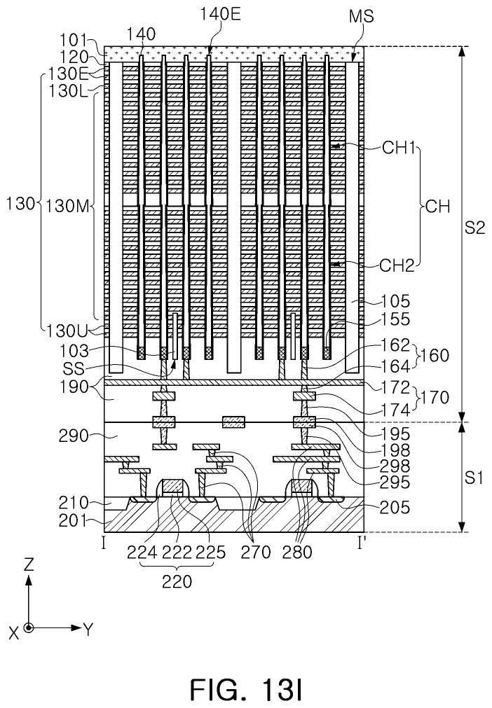

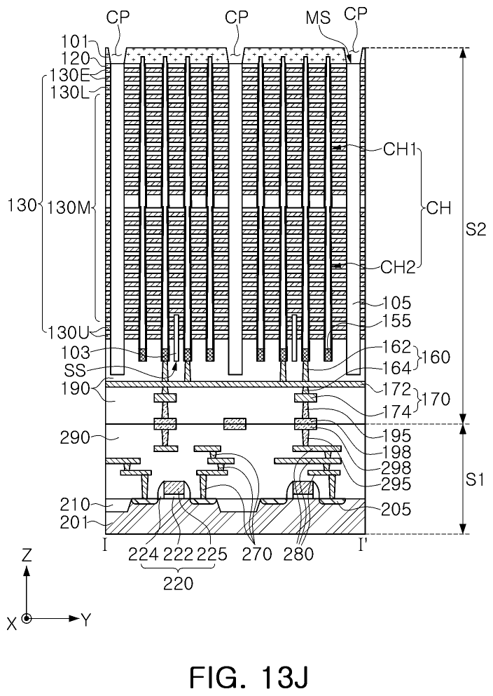

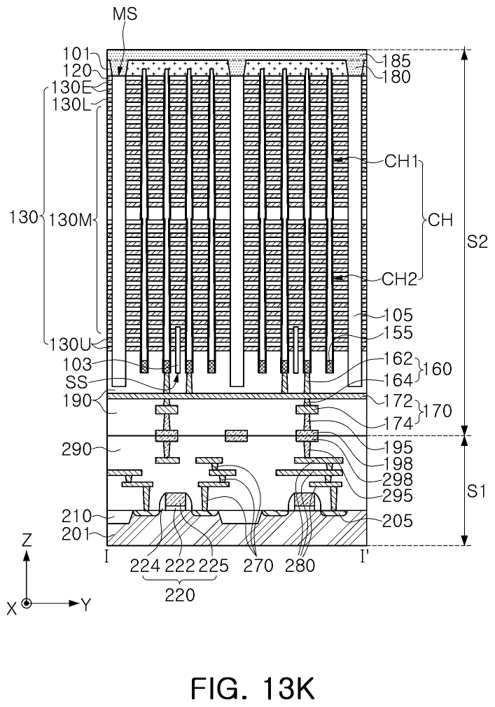

FIGS. 13A to 13K are schematic cross-sectional views illustrating a method of manufacturing a semiconductor device according to embodiments of the present inventive concept. FIGS. 13A to 13K illustrate regions corresponding to FIG. 2.

Referring to FIG. 13A, a first substrate structure S1 including circuit elements 220, first interconnection structures, and a first bonding structure may be formed on a substrate 201.

Device isolation layers 210 may be formed in the substrate 201, and a circuit gate dielectric layer 222 and a circuit gate electrode 225 may be sequentially formed on the substrate 201. In an embodiment, the device isolation layers 210 may be formed by, for example, a shallow trench isolation (STI) process. In an embodiment, the circuit gate dielectric layer 222 and the circuit gate electrode 225 may be formed using atomic layer deposition (ALD) or chemical vapor deposition (CVD). The circuit gate dielectric layer 222 may be formed of silicon oxide, and the circuit gate electrode 225 may be formed of at least one of polycrystalline silicon or a metal silicide layer. However, embodiments of the present inventive concept are not necessarily limited thereto. A spacer layer 224 and source/drain regions 205 may then be formed on both sidewalls of the circuit gate dielectric layer 222 and the circuit gate electrode 225. In some embodiments, the spacer layer 224 may be formed of a plurality of layers. In an embodiment, the source/drain regions 205 may be formed by performing an ion implantation process.

In an embodiment, the circuit contact plugs 270 of the first interconnection structure and the first bonding vias 295 of the first bonding structure may be formed by partially forming and then partially removing the peripheral region insulating layer 290 by etching, and by filling a portion in which the peripheral region insulating layer 290 was removed with a conductive material. The circuit interconnection lines 280 of the first interconnection structure and the first bonding metal layers 298 of the first bonding structure may be formed, for example, by depositing a conductive material and then patterning the same. The first bonding metal layers 298 may be formed such that upper surfaces thereof are exposed through the peripheral region insulating layer 290. Upper surfaces of the first bonding metal layers 298 may form a portion of the upper surface of the first substrate structure S1.

In an embodiment, the peripheral region insulating layer 290 may be formed of a plurality of insulating layers. A portion of the peripheral region insulating layer 290 may be formed in respective operations of forming the first interconnection structure and the first bonding structure. By this operation, the first substrate structure S1 may be prepared.

Referring to FIG. 13B, a process of manufacturing the second substrate structure S2 may include alternately stacking sacrificial insulating layers 118 and interlayer insulating layers 120 on a base substrate SUB (e.g., in the Z direction), and then forming channel sacrificial layers 129.

The base substrate SUB may be removed through a subsequent process. In an embodiment, the base substrate SUB may be a semiconductor substrate such as a silicon (S1) wafer.

The sacrificial insulating layers 118 may be alternately formed with the interlayer insulating layers 120 to form a lower stack structure and an upper stack structure. After the lower stack structure is formed, the channel sacrificial layers 129 may be formed, and the upper stack structure may be formed.

The sacrificial insulating layers 118 may be replaced by the gate electrodes 130 (refer to FIG. 2) through a subsequent process. For example, the sacrificial insulating layers 118 may be formed of a material that may be etched with etch selectivity with respect to the interlayer insulating layers 120. In an embodiment, the interlayer insulating layer 120 may be formed of at least one compound selected from silicon oxide and silicon nitride, and the sacrificial insulating layers 118 may be formed of a material selected from silicon, silicon oxide, silicon carbide, and silicon nitride, which is the material different from a material of the interlayer insulating layer 120. In an embodiment, the thicknesses of the interlayer insulating layers 120 may not all be the same. For example, the thicknesses of at least some of the interlayer insulating layers 120 may be different from the thicknesses of other of the interlayer insulating layers 120.

In an embodiment, the channel sacrificial layers 129 may be formed by forming lower channel holes penetrating through the lower stack structure in a region corresponding to the first channel structures CH1 (refer to FIG. 2) and then depositing a material for the channel sacrificial layers 129 in the lower channel holes. In an embodiment, the lower channel holes may be formed to partially recess the base substrate SUB from the upper surface. However, embodiments of the present inventive concept are not necessarily limited thereto. The channel sacrificial layers 129 may include, for example, polycrystalline silicon. In this operation, a portion of the cell region insulating layer 190 covering the stack structure of the sacrificial insulating layers 118 may be formed.

Referring to FIG. 13C, the channel structures CH passing through the stack structure of the sacrificial insulating layers 118 and the interlayer insulating layers 120 may be formed.

In the upper stack structure, the upper insulating regions SS may be formed by removing portions of the sacrificial insulating layers 118 and the interlayer insulating layers 120. In an embodiment, to form the upper insulating regions SS, a separate mask layer may be used to expose the region in which the upper insulating regions SS are to be formed, and a predetermined number of sacrificial insulating layers 118 and interlayer insulating layers 120 may be removed from the top. Then, an insulating material may be deposited, thereby forming the upper insulating layer 103.

The upper stack structure on the channel sacrificial layers 129 may anisotropically etched to form upper channel holes, and the channel sacrificial layers 129 exposed through the upper channel holes may be removed to form the channel structures CH. Accordingly, channel holes in which the lower channel holes and the upper channel holes are connected (e.g., directly connected) may be formed.

A channel dielectric layer 145, a channel layer 140, a channel filling insulating layer 150, and a channel pad 155 are then sequentially formed in each of the channel holes to form the channel structures CH including the first and second channel structures CH1 and CH2. The channel layer 140 may be formed on (e.g., formed directly thereon) the channel dielectric layer 145 in the channel structures CH. The channel filling insulating layer 150 may be formed to fill the channel structures CH, and may be an insulating material. However, embodiments of the present inventive concept are not necessarily limited thereto. For example, in some embodiments, the space between the channel layers 140 may be filled with a conductive material instead of the channel filling insulating layer 150. The channel pads 155 may be formed of a conductive material, for example, doped polycrystalline silicon.

Referring to FIG. 13D, openings OP passing through the stack structure of the sacrificial insulating layers 118 and the interlayer insulating layers 120 may be formed, and the sacrificial insulating layers 118 may be removed through the openings OP, thereby forming tunnel portions TL.

The openings OP may be formed in a region corresponding to the separation regions MS (refer to FIG. 2), and may be formed in the form of a trench extending in the X direction. In an embodiment, the openings OP may be formed to partially recess the base substrate SUB from the upper surface. However, embodiments of the present inventive concept are not necessarily limited thereto. In an embodiment, the lower portion of the openings OP may be co-planar with the lower portions of the channel structures CH.

In an embodiment, the sacrificial insulating layers 118 may be selectively removed with respect to the interlayer insulating layers 120 using, for example, wet etching. Accordingly, tunnel portions TL may be formed between the interlayer insulating layers 120 (e.g., in the Z direction).

Referring to FIG. 13E, after the gate electrodes 130 are formed in the region from which the sacrificial insulating layers 118 have been removed and the separation regions MS are formed, second interconnection structures and a second bonding structure may be formed.

The gate electrodes 130 may be formed by filling the tunnel portions TL with a conductive material. In an embodiment, the gate electrodes 130 may include a metal, polycrystalline silicon, or a metal silicide material.

In some embodiments, a dielectric layer may be formed prior to forming the gate electrodes 130. In this embodiment, it may be understood that the dielectric layer forms a blocking structure together with the blocking layer of the channel dielectric layer 145 extending vertically along the channel structure CH. The dielectric layer may be formed to extend horizontally along the tunnel portions TL, and may be formed to cover sidewalls of the channel structures CH exposed through the tunnel portions TL.

The separation regions MS may be formed by depositing the isolation insulating layer 105 by filling the openings OP with an insulating material.

In the second interconnection structure, the cell contact plugs 160 may be formed on the channel pads 155 by etching the cell region insulating layer 190 and depositing a conductive material. In an embodiment, the cell interconnection lines 170 may be formed through a process of depositing and patterning a conductive material, or may be formed by partially forming an insulating layer constituting the cell region insulating layer 190 and patterning the same and depositing a conductive material.

The second bonding vias 195 and the second bonding metal layers 198 constituting the second bonding structure may be formed by further forming the cell region insulating layer 190 on the cell interconnection lines 170 and then partially removing the same and depositing a conductive material on portions of the cell region insulating layer 190 that have been removed. Upper surfaces of the second bonding metal layers 198 may be exposed from the cell region insulating layer 190. The upper surfaces of the second bonding metal layers 198 may form a portion of the upper surface of the second substrate structure S2.

Referring to FIG. 13F, the first substrate structure S1 and the second substrate structure S2 may be bonded to each other.

The first substrate structure S1 and the second substrate structure S2 may be connected by bonding the first bonding metal layers 298 and the second bonding metal layers 198 by pressing them towards each other. Simultaneously, the bonding insulating layers that are portions of the peripheral region insulating layer 290 and the cell region insulating layer 190 may also be bonded by pressing them towards each other. After the second substrate structure S2 is turned over on the first substrate structure S1 such that the second bonding metal layers 198 face downward, bonding may be performed.

The first substrate structure S1 and the second substrate structure S2 may be directly bonded to each other without the intervening of an adhesive such as a separate adhesive layer. According to an embodiment, before bonding the first substrate structure S1 and the second substrate structure S2 to each other, a surface treatment process such as hydrogen plasma treatment may be further performed on the upper surface of the first substrate structure S1 and the lower surface of the second substrate structure S2 to provide an increased bonding strength.

Referring to FIG. 13G, the base substrate SUB of the second substrate structure S2 may be removed on the bonding structure of the first and second substrate structures S1 and S2.

In an embodiment, a portion of the base substrate SUB may be removed from the upper surface by a polishing process such as a grinding process, and the remaining part may be removed by an etching process such as wet etching and/or dry etching. Alternatively, the entire base substrate SUB may be removed by an etching process. For example, when the channel dielectric layer 145 and the isolation insulating layer 105 include an oxide, the etching process may be performed by setting conditions such that the etching is stopped in the oxide. Accordingly, only the base substrate SUB is selectively removed, and therefore, in the region in which the base substrate SUB has been removed, the isolation insulating layers 105 and the channel structures CH may protrude on an uppermost interlayer insulating layer 120.

Referring to FIG. 13H, the channel dielectric layers 145 exposed on the upper ends of the channel structures CH may be removed.

As the upper ends of the channel structures CH protrude upwardly of the uppermost interlayer insulating layer 120, upper regions of the channel dielectric layers 145, which are the outermost layers of the channel structures CH may be exposed upwards. By removing the portions of the channel dielectric layers 145 that are exposed upwards as described above, the upper ends 140E of the channel layers 140 may be exposed. In an embodiment, the channel dielectric layers 145 may be selectively removed by a wet etching and/or a dry etching process. In some embodiments, the channel dielectric layers 145 may be further removed by recessing downwards. In this embodiment, the upper ends of the channel dielectric layers 145 may be positioned on a level lower than the upper surface of the uppermost interlayer insulating layer 120.

In this operation, protruding upper regions of the isolation insulating layers 105 may also be removed. Accordingly, upper surfaces of the isolation insulating layers 105 may form a flat surface with the upper surface of the uppermost interlayer insulating layer 120. In some embodiments, the isolation insulating layers 105 may be further removed to be recessed downwards than illustrated in FIG. 13H.

Referring to FIG. 13I, the plate layer 101 may be formed on upper portions of the second substrate S2.

In an embodiment, the plate layer 101 may be formed by, for example, depositing a semiconductor material such as silicon, and annealing and crystallizing the same. The plate layer 101 may include, for example, impurities such as N-type impurities doped in-situ, or impurities implanted through a separate process.

In an embodiment, the deposition process is performed at a relatively low temperature in terms of crystallization, such that the semiconductor material may be deposited in a state that is not completely crystallized. By additionally performing a heat treatment process such as laser annealing for crystallization of the semiconductor material, the semiconductor material may be crystallized or crystallinity thereof may be increased, thereby reducing the resistance of the plate layer 101.

Referring to FIG. 13J, contact openings CP may be formed by partially removing the plate layer 101.

In an embodiment, the contact openings CP may be formed by removing the plate layer 101 disposed on the separation regions MS. The isolation insulating layers 105 may be exposed through the bottom surfaces of the contact openings CP.

The embodiments of FIGS. 10A and 10B may be manufactured by adjusting a depth of the contact openings CP in this step.

The embodiment of FIGS. 11A and 11B may be manufactured, for example, by forming the contact openings CP in the base substrate SUB in this operation, after performing the same processes as described above with reference to FIGS. 13A to 13F. In this embodiment, the base substrate SUB may form the plate layer 101. In an embodiment, prior to performing this operation, the base substrate SUB may be removed by a predetermined thickness to be thinned, and an impurity implantation process may be further performed to the base substrate SUB.

Referring to FIG. 13K, source contacts 180 filling the contact openings CP may be formed, and a source interconnection layer 185 may be formed.

The source contacts 180 and the source interconnection layer 185 may be formed by depositing a conductive material. In an embodiment, the source contacts 180 and the source interconnection layer 185 may be formed by a single deposition process. However, embodiments of the present inventive concept are not necessarily limited thereto.

Next, referring to FIG. 2 together, the semiconductor device 100 of FIG. 2 may be finally manufactured by forming the anti-reflection layer 189 on (e.g., directly thereon) the source interconnection layer 185.

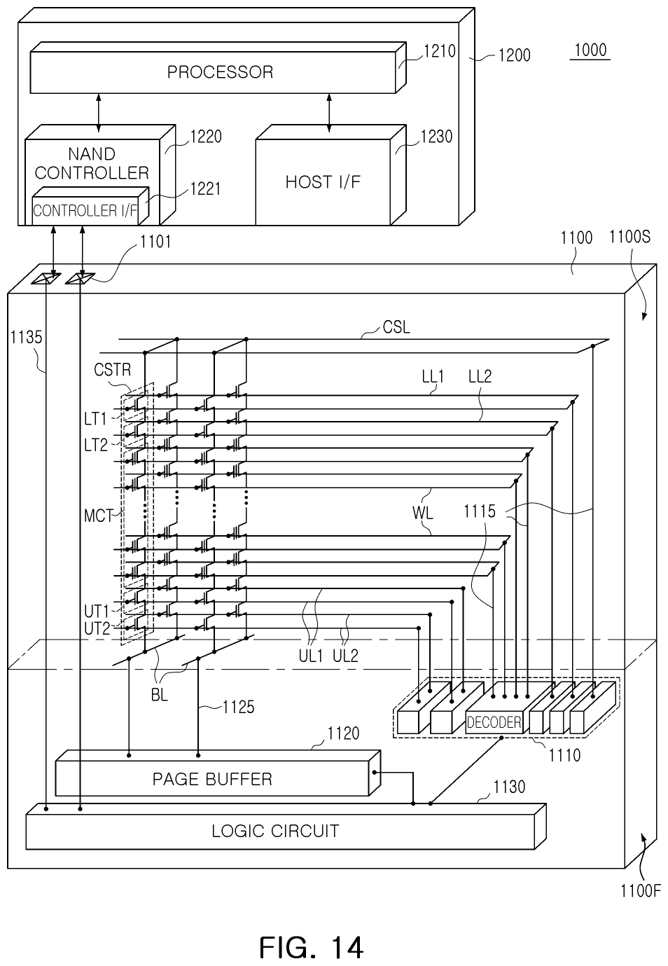

FIG. 14 is a diagram schematically illustrating a data storage system including a semiconductor device according to an embodiment of the present inventive concept.

Referring to FIG. 14, a data storage system 1000 may include a semiconductor device 1100 and a controller 1200 electrically connected to the semiconductor device 1100. The data storage system 1000 may be a storage device including one or a plurality of semiconductor devices 1100 or an electronic device including a storage device. For example, in an embodiment the data storage system 1000 may be a solid state drive device (SSD), a universal serial bus (USB), a computing system, a medical device, or a communication device, including one or a plurality of semiconductor devices 1100. However, embodiments of the present inventive concept are not necessarily limited thereto.

The semiconductor device 1100 may be a nonvolatile memory device, for example, the NAND flash memory device described above with reference to FIGS. 1 to 12. The semiconductor device 1100 may include a first structure 1100F and a second structure 1100S on the first structure 1100F. In an embodiment, the first structure 1100F may be disposed next to the second structure 1100S. In an embodiment, the first structure 1100F may be a peripheral circuit structure including a decoder circuit 1110, a page buffer 1120, and a logic circuit 1130. The second structure 1100S may be a memory cell structure including a bit line BL, a common source line CSL, word lines WL, first and second upper gate lines UL1 and UL2, first and second lower gate lines LL1 and LL2, and memory cell strings CSTR between the bit line BL and the common source line CSL.

In the second structure 1100S, each of the memory cell strings CSTR may include lower transistors LT1 and LT2 adjacent to the common source line CSL, upper transistors UT1 and UT2 adjacent to the bit line BL, and a plurality of memory cell transistors MCT disposed between the lower transistors LT1 and LT2 and the upper transistors UT1 and UT2. The number of the lower transistors LT1 and LT2 and the number of the upper transistors UT1 and UT2 may be variously modified according to embodiments and are not necessarily limited to the number shown in FIG. 14.

In an embodiment, the upper transistors UT1 and UT2 may include a string select transistor, and the lower transistors LT1 and LT2 may include a ground select transistor. The lower gate lines LL1 and LL2 may be gate electrodes of the lower transistors LT1 and LT2, respectively. The word lines WL may be gate electrodes of the memory cell transistors MCT, and the upper gate lines UL1 and UL2 may be gate electrodes of the upper transistors UT1 and UT2, respectively.

In an embodiment, the lower transistors LT1 and LT2 may include a lower erase control transistor LT1 and a ground select transistor LT2 connected in series. The upper transistors UT1 and UT2 may include a string select transistor UT1 and an upper erase control transistor UT2 connected in series. At least one of the lower erase control transistor LT1 and the upper erase control transistor UT2 may be used for an erase operation of erasing data stored in the memory cell transistors MCT using the GIDL phenomenon.

The common source line CSL, the first and second lower gate lines LL1 and LL2, the word lines WL, and the first and second upper gate lines UL1 and UL2 may be electrically connected to the decoder circuit 1110 through first connection wires 1115 extending from the inside of the first structure 1100F to the second structure 1100S. The bit lines BL may be electrically connected to the page buffer 1120 through second connection wires 1125 extending from the inside of the first structure 1100F to the second structure 1100S.

In the first structure 1100F, the decoder circuit 1110 and the page buffer 1120 may perform a control operation on at least one selected memory cell transistor among the plurality of memory cell transistors MCT. The decoder circuit 1110 and the page buffer 1120 may be controlled by the logic circuit 1130. In an embodiment, the semiconductor device 1100 may communicate with the controller 1200 through an input/output pad 1101 electrically connected to the logic circuit 1130. The input/output pad 1101 may be electrically connected to the logic circuit 1130 through an input/output connection wire 1135 extending from the inside of the first structure 11001F to the second structure 1100S.

In an embodiment, the controller 1200 may include a processor 1210, a NAND controller 1220, and a host interface 1230 (HOST I/F in FIG. 14). In some embodiments, the data storage system 1000 may include a plurality of semiconductor devices 1100, and in this embodiment, the controller 1200 may control the plurality of semiconductor devices 1100.

The processor 1210 may control the overall operation of the data storage system 1000 including the controller 1200. The processor 1210 may operate according to a predetermined firmware, and may access the semiconductor device 1100 by controlling the NAND controller 1220. The NAND controller 1220 may include a controller interface 1221 (CONTROLLER I/F in FIG. 14) that processes communication with the semiconductor device 1100. Through the controller interface 1221, a control command may be transmitted for controlling the semiconductor device 1100 with respect to data to be written to the memory cell transistors MCT of the semiconductor device 1100, data to be read from the memory cell transistors MCT, and the like. The host interface 1230 may provide a communication function between the data storage system 1000 and an external host. When receiving a control command from an external host through the host interface 1230, the processor 1210 may control the semiconductor device 1100 in response to the control command.

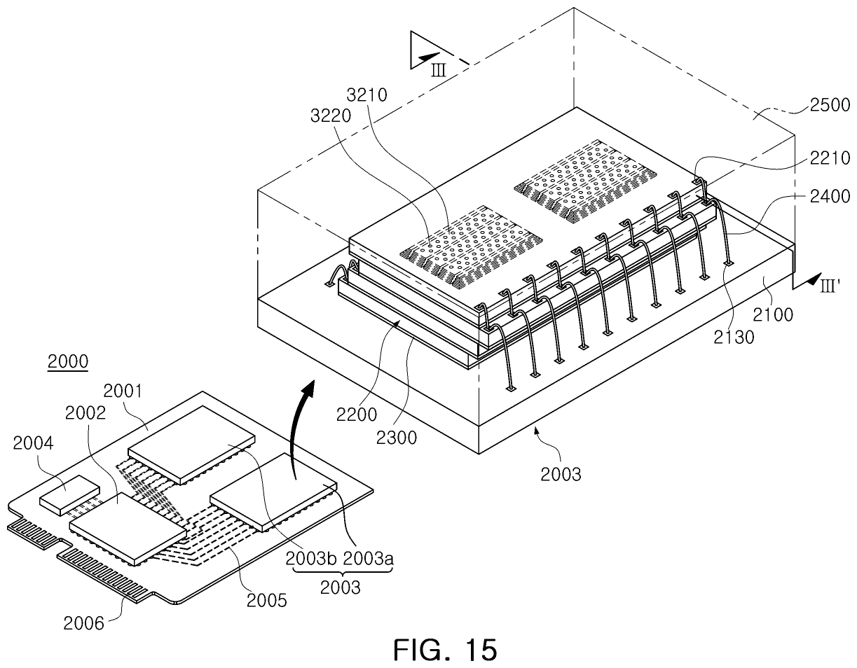

FIG. 15 is a schematic perspective view of a data storage system including a semiconductor device according to an embodiment of the present inventive concept.

Referring to FIG. 15, a data storage system 2000 according to an embodiment of the present inventive concept may include a main board 2001, a controller 2002 mounted on the main board 2001, one or more semiconductor packages 2003, and a DRAM 2004. The semiconductor package 2003 and the DRAM 2004 may be connected to the controller 2002 by interconnection patterns 2005 formed on the main board 2001.

The main board 2001 may include a connector 2006 including a plurality of pins coupled to an external host. The number and arrangement of the plurality of pins in the connector 2006 may vary according to a communication interface between the data storage system 2000 and the external host. In an embodiment, the data storage system 2000 may communicate with an external host according to any one of the interfaces such as a Universal Serial Bus (USB), Peripheral Component Interconnect Express (PCI-Express), Serial Advanced Technology Attachment (SATA), an M-Phy for Universal Flash Storage (UFS), and the like. However, embodiments of the present inventive concept are not necessarily limited thereto. In an embodiment, the data storage system 2000 may operate by power supplied from an external host through the connector 2006. The data storage system 2000 may further include a power management integrated circuit (PMIC) for distributing power supplied from the external host to the controller 2002 and the semiconductor package 2003.

The controller 2002 may write data to or read data from the semiconductor package 2003, and may increase the operating speed of the data storage system 2000.

In an embodiment, the DRAM 2004 may be a buffer memory for reducing a speed difference between the semiconductor package 2003 as a data storage space and an external host. The DRAM 2004 included in the data storage system 2000 may also operate as a type of cache memory, and may provide a space for temporarily storing data in a control operation for the semiconductor package 2003. For example, in an embodiment in which the data storage system 2000 includes the DRAM 2004, the controller 2002 may further include a DRAM controller for controlling the DRAM 2004 in addition to the NAND controller for controlling the semiconductor package 2003.

In an embodiment, the semiconductor package 2003 may include first and second semiconductor packages 2003a and 2003b spaced apart from each other. Each of the first and second semiconductor packages 2003a and 2003b may be a semiconductor package including a plurality of semiconductor chips 2200. Each of the first and second semiconductor packages 2003a and 2003b may include a package substrate 2100, the semiconductor chips 2200 on the package substrate 2100, adhesive layers 2300 disposed on lower surfaces of the semiconductor chips 2200, respectively, a connection structure 2400 electrically connecting the semiconductor chips 2200 and the package substrate 2100, and a molding layer 2500 covering the semiconductor chips 2200 and the connection structure 2400 on the package substrate 2100.

The package substrate 2100 may be a printed circuit board including upper package pads 2130. Each semiconductor chip 2200 may include an input/output pad 2210. The input/output pad 2210 may correspond to the input/output pad 1101 of FIG. 14. Each of the semiconductor chips 2200 may include gate stack structures 3210 and channel structures 3220. Each of the semiconductor chips 2200 may include the semiconductor device described above with reference to FIGS. 1 to 12.

In an embodiment, the connection structure 2400 may be a bonding wire electrically connecting the input/output pad 2210 and the upper package pads 2130. Accordingly, in each of the first and second semiconductor packages 2003a and 2003b, the semiconductor chips 2200 may be electrically connected to each other by a bonding wire method, and may be electrically connected to the upper package pads 2130 of the package substrate 2100. In an embodiment, in each of the first and second semiconductor packages 2003a and 2003b, the semiconductor chips 2200 may also be electrically connected to each other by a connection structure including a Through Silicon Via (TSV) instead of the connection structure 2400 of the bonding wire method.

In an embodiment, the controller 2002 and the semiconductor chips 2200 may be included in one package. In an embodiment, the controller 2002 and the semiconductor chips 2200 may be mounted on a separate interposer substrate different from the main board 2001, and the controller 2002 and the semiconductor chips 2200 may be connected to each other by interconnections formed on the interposer substrate.

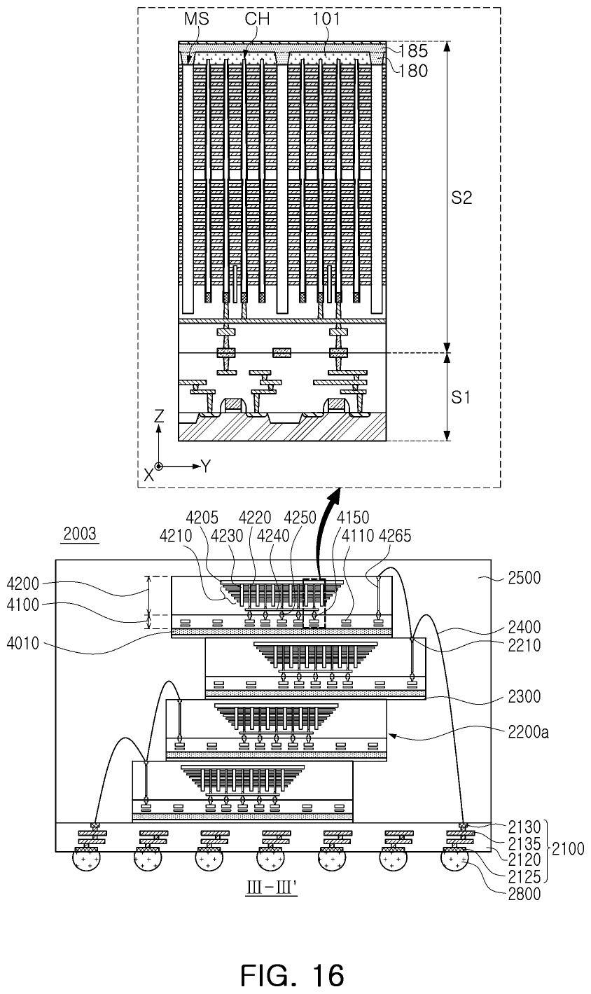

FIG. 16 is a cross-sectional view schematically illustrating a semiconductor package according to an embodiment of the present inventive concept. FIG. 16 illustrates an embodiment of the semiconductor package 2003 of FIG. 15, and conceptually illustrates a region taken along line III-III′ of the semiconductor package 2003 of FIG. 15.

Referring to FIG. 16, in the semiconductor package 2003A, each of the semiconductor chips 2200a may include a semiconductor substrate 4010, a first structure 4100 on the semiconductor substrate 4010, and a second structure 4200 disposed on the first structure 4100 and bonded to the first structure 4100 by a wafer bonding method.

The first structure 4100 may include a peripheral circuit region including a peripheral interconnection 4110 and first bonding structures 4150. The second structure 4200 may include a common source line 4205, a gate stack structure 4210 between the common source line 4205 and the first structure 4100, memory channel structures 4220 and a separation region 4230 passing through the gate stack structure 4210, and second bonding structures 4250 electrically connected to the word lines WL (refer to FIG. 14) of the gate stack structure 4210 and the memory channel structures 4220, respectively. For example, the second bonding structures 4250 may be electrically connected to the memory channel structures 4220 and the word lines WL, respectively, through the bit lines 4240 electrically connected to the memory channel structures 4220 and the gate contacts 165 (refer to FIG. 8B) electrically connected to the word lines WL. The first bonding structures 4150 of the first structure 4100 and the second bonding structures 4250 of the second structure 4200 may be bonded to each other while being in direct contact with each other. In an embodiment, bonded portions of the first bonding structures 4150 and the second bonding structures 4250 may be formed of, for example, copper (Cu).

As illustrated in the enlarged view, the second structure 4200 may include source contacts 180 and channel structures CH, which are physically and electrically connected to the plate layer 101 that corresponds to a common source line, and may further include a source interconnection layer 185 connected to the source contacts 180. Each of the semiconductor chips 2200a may further include an input/output pad 2210 and an input/output connection wire 4265 below the input/output pad 2210. The input/output connection wire 4265 may be electrically connected to a portion of the second bonding structures 4250.

The semiconductor chips 2200a may be electrically connected to each other by connection structures 2400 in the form of bonding wires. However, in some embodiments, semiconductor chips in one semiconductor package, such as the semiconductor chips 2200a, may be electrically connected to each other by a connection structure including a Through Silicon Via (TSV).

As set forth above, in a structure in which two or more substrate structures are bonded, the structure of the source contacts and a source interconnection layer connected to a common source line may be configured so that a semiconductor device having increased electrical characteristics and reliability and a data storage system including the same may be provided.

While non-limiting embodiments have been illustrated and described above, it will be apparent to those skilled in the art that modifications and variations could be made without departing from the scope of the present inventive concept.

What is claimed is:

1. A semiconductor device comprising:
a first substrate structure including a substrate, circuit elements on the substrate, and first bonding metal layers on the circuit elements; and
a second substrate structure disposed directly on the first substrate structure, the second substrate structure electrically connected to the first substrate structure,
wherein the second substrate structure includes,
a plate layer comprising a conductive material;
gate electrodes stacked below the plate layer and spaced apart from each other in a first direction that is perpendicular to a lower surface of the plate layer;
channel structures passing through the gate electrodes and extending in the first direction, each of the channel structures including a channel layer;
separation regions extending in the first direction and a second direction that is perpendicular to the first direction, the separation regions penetrating through the gate electrodes and being spaced apart from each other in a third direction that is perpendicular to the first and second directions;
source contacts in the plate layer and disposed on the separation regions, the source contacts extending in the second direction; and
second bonding metal layers below the channel structures and the gate electrodes and directly connected to the first bonding metal layers, and
the plate layer is in direct contact with lateral side surfaces of the source contacts and an upper end of the channel layer of each of the channel structures, and is electrically connected to the source contacts and the channel layer.

2. The semiconductor device of claim 1, wherein upper surfaces of the source contacts are coplanar with an upper surface of the plate layer.

3. The semiconductor device of claim 1, wherein the second substrate structure further includes a source interconnection layer on the source contacts and covering an upper surface of the plate layer.

4. The semiconductor device of claim 3, wherein the second substrate structure further includes an anti-reflection layer on the source interconnection layer.

5. The semiconductor device of claim 1, wherein the second substrate structure further includes:
source interconnection layers on the source contacts, each of the source interconnection layers having a line shape extending in the third direction; and
vias connecting the source contacts and the source interconnection layers in regions that the source contacts and the source interconnection layers intersect each other.

6. The semiconductor device of claim 1, wherein the second substrate structure further includes at least one source interconnection layer having a line shape connected to end portions of the source contacts in the second direction, the at least one source interconnection layer extending in the third direction.

7. The semiconductor device of claim 6, wherein the at least one source interconnection layer is positioned on a substantially same level as a level of the source contacts.

8. The semiconductor device of claim 1, wherein:
the plate layer is a semiconductor layer including N-type impurities; and
the source contacts include a metallic material.

9. The semiconductor device of claim 1, wherein:
the upper end of the channel layer includes an upper surface and an upper region of a lateral side surface connected to the upper surface,
wherein the upper end of the channel layer is surrounded by the plate layer.

10. The semiconductor device of claim 1, wherein:
each of the channel structures includes a channel dielectric layer, the channel layer, and a channel filling layer sequentially stacked in a channel hole; and
the upper end of the channel layer is exposed by the channel dielectric layer.

11. The semiconductor device of claim 1, wherein the plate layer has a thickness in a range of about 10 nm to about 150 nm.

12. The semiconductor device of claim 1, wherein:
the separation regions comprise an insulating material; and
lower surfaces of the source contacts are in direct contact with the separation regions.

13. The semiconductor device of claim 1, wherein lower surfaces of the source contacts are in the plate layer.

14. A semiconductor device comprising:
a first substrate structure including a substrate and circuit elements on the substrate; and
a second substrate structure disposed directly on the first substrate structure, the second substrate structure electrically connected to the first substrate structure,
wherein the second substrate structure includes,
a plate layer;
gate electrodes stacked below the plate layer and spaced apart from each other in a first direction that is perpendicular to a lower surface of the plate layer;
channel structures passing through the gate electrodes and extending in the first direction, each of the channel structures including a channel layer;
separation regions extending in the first direction and a second direction that is perpendicular to the first direction, the separation regions penetrating through the gate electrodes and being spaced apart from each other in a third direction that is perpendicular to the first and second directions;
source contacts in the plate layer and disposed on the separation regions, the source contacts extending in the second direction;
at least one source interconnection layer on upper surfaces or first side surfaces of the source contacts, the at least one source interconnection layer is electrically connected to the source contacts; and
the source contacts have second side surfaces in direct contact with the plate layer, and lower surfaces of the source contacts are in direct contact with the separation regions.

15. The semiconductor device of claim 14, wherein the source contacts pass through the plate layer.

16. The semiconductor device of claim 14, wherein:
the separation regions comprise an insulating material; and
the source contacts are electrically connected to the plate layer through the second side surfaces.

17. The semiconductor device of claim 14, wherein the source interconnection layer has a plate shape and covers an upper surface of the plate layer.

18. The semiconductor device of claim 14, wherein the source interconnection layer has a line shape extending in the third direction.

19. A data storage system comprising:
a semiconductor storage device including a first substrate structure having circuit elements and first bonding metal layers, a second substrate structure including channel structures and second bonding metal layers connected to the first bonding metal layers, and an input/output pad electrically connected to the circuit elements; and
a controller electrically connected to the semiconductor storage device through the input/output pad and controlling the semiconductor storage device,
wherein the second substrate structure further includes,
a plate layer;
gate electrodes stacked below the plate layer and spaced apart from each other in a first direction that is perpendicular to a lower surface of the plate layer;
separation regions extending in the first direction and a second direction that is perpendicular to the first direction, the separation regions penetrating through the gate electrodes and being spaced apart from each other in a third direction that is perpendicular to the first and second directions;
source contacts in the plate layer and disposed on the separation regions, the source contacts extending in the second direction; and
at least one source interconnection layer on upper surfaces or first side surfaces of the source contacts, the at least one source interconnection layer is electrically connected to the source contacts, and
the source contacts have second side surfaces in direct contact with the plate layer.

20. The data storage system of claim 19, wherein:
each of the channel structures includes a channel layer comprising a semiconductor material; and
the plate layer surrounds and directly contacts an upper end of the channel layer of each of the channel structures.
